(19) United States
(12) Patent Application Publication
(10) Pub. No.: US 2026/0107512 A1
(43) Pub. Date: Apr. 16, 2026

(54) SEMICONDUCTOR STRUCTURE AND METHOD FOR FORMING THE SAME

(71) Applicant: Taiwan Semiconductor Manufacturing Company, Ltd., Hsinchu (TW)

(72) Inventor: Jhon-Jhy LIAW, Zhudong Township (TW)

(73) Assignee: Taiwan Semiconductor Manufacturing Company, Ltd., Hsinchu (TW)

(21) Appl. No.: 18/913,189

(22) Filed: Oct. 11, 2024

(51) Int. Cl. H01L 29/423; H01L 21/762; H01L 21/8238; H01L 27/092; H01L 29/06; H01L 29/08; H01L 29/417; H01L 29/66; H01L 29/775; H01L 29/786

(52) U.S. Cl. CPC H10D 30/6735; H10D 30/014; H10D 30/43; H10D 30/6757; H10D 62/121; H10D 62/151; H10D 64/017; H10D 64/018; H10D 64/251; H10D 84/017; H10D 84/038; H10D 84/85; H10W 10/014; H10W 10/17

(57) ABSTRACT

A semiconductor structure includes a substrate, first nanostructures arranged over the substrate, and a first gate structure wrapped around the first nanostructures. The semiconductor structure further includes first gate spacers formed on opposite sides of the first gate structure and over a topmost one of the first nanostructures, first source/drain features attached to opposite sides of the first nanostructures, and a second bottom dielectric layer formed over the substrate and below the first gate structure. Each of the first source/drain features includes a first bottom dielectric layer and a first epitaxial layer over the first bottom dielectric layer. The first bottom dielectric layer is vertically sandwiched between the substrate and the first epitaxial layer. The second bottom dielectric layer is vertically sandwiched between the substrate and the first gate structure, and the second bottom dielectric layer is in contact with the first bottom dielectric layers.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs and, for these advancements to be realized, similar developments in IC processing and manufacturing are needed.

As integrated circuit (IC) technologies progress towards smaller technology nodes, multi-gate metal-oxide-semiconductor field effect transistor (multi-gate MOSFET, or multi-gate devices) have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Gate-all-around (GAA) transistors are examples of multi-gate devices that have become popular and promising candidates for high performance and low leakage applications. A GAA transistor has a gate structure that can extend, partially or fully, around a channel region to provide access to the channel region on two or more sides. While existing GAA transistors may be generally adequate for their intended purposes, they are not entirely satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a fragmentary diagrammatic top view of an integrated circuit (IC) chip, in portion or entirety, in accordance with some embodiments of the present disclosure.

FIGS. 2A, 2B, 2C, 2D, and 2E are circuit schematics of various STD cells in the array of circuit cells in the logic region of the IC chip, in accordance with some embodiments of the present disclosure.

FIG. 3 is a perspective view of a GAA transistor in the array of circuit cells, in accordance with some embodiments of the present disclosure.

FIG. 4 illustrates a fragmentary diagrammatic top view (or layout) of a semiconductor structure in the logic region of the IC chip, in accordance with some embodiments of the present disclosure.

FIG. 5A illustrates a cross-sectional view of the semiconductor structure along line A-A in FIG. 4, in accordance with some embodiments of the present disclosure.

FIG. 5B illustrates a cross-sectional view of the semiconductor structure along line B-B in FIG. 4, in accordance with some embodiments of the present disclosure.

FIG. 5C illustrates a cross-sectional view of the semiconductor structure along line C-C in FIG. 4, in accordance with some embodiments of the present disclosure.

FIG. 5D illustrates a cross-sectional view of the semiconductor structure along line D-D in FIG. 4, in accordance with some embodiments of the present disclosure.

FIGS. 6A, 7A, and 8A illustrate cross-sectional views of the semiconductor structure along line A-A in FIG. 4, in accordance with some alternative embodiments of the present disclosure.

FIGS. 6B, 7B, 7D, 8B, and 9 illustrate cross-sectional views of the semiconductor structure along line B-B in FIG. 4, in accordance with some alternative embodiments of the present disclosure.

FIGS. 6C, 7C, 7E, and 8C illustrates a cross-sectional view of the semiconductor structure along a line D-D in FIG. 4, in accordance with some alternative embodiments of the present disclosure.

FIG. 10 is a Y-Z cross-sectional view of the semiconductor structure at A fabrication stage along a line C-C of FIG. 4, in accordance with some embodiments of the present disclosure.

FIGS. 11A, 12A, 13A, 14A, 15A, 16A, 17A, 18A, 19A, 20A, 21A, 22A, and 23A are X-Z cross-sectional views of the semiconductor structure at various fabrication stages along line A-A of FIG. 4, in accordance with some embodiments of the present disclosure.

FIGS. 11B, 12B, 13B, 14B, 15B, 16B, 17B, 18B, 19B, 20B, 21B, 22B, and 23B are X-Z cross-sectional views of the semiconductor structure at various fabrication stages along line B-B of FIG. 4, in accordance with some embodiments of the present disclosure.

FIGS. 11C, 12C, 13C, 14C, 15C, 16C, 17C, 18C, 19C, 20C, 21C, 22C, and 23C are Y-Z cross-sectional views of the semiconductor structure at various fabrication stages along line C-C of FIG. 4, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally related to semiconductor structures, and more particularly to semiconductor structures with field-effect transistors (FETs), such as three-dimensional gate-all-around (GAA) transistors, in memory (e.g., SRAM) and/or standard logic cells of an integrated circuit (IC) structure. Generally, a GAA transistor may include a plurality of vertically stacked nanostructures (e.g., nanosheets, nanowires, or nanorods) in a channel region of the transistor, thereby allowing better gate control, lowered leakage current, and improved scaling capability for various IC applications.

The gate-all-around (GAA) transistor structures described below may be patterned by any suitable method. For example, the structures may be patterned by using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments of the present disclosure offer advantages over the existing art, though it should be understood that other embodiments may offer different advantages, not all advantages are necessarily discussed herein, and no particular advantage is required for all embodiments. For example, embodiments discussed herein include a gate bottom dielectric layer formed below the gate structure and between the gate structure and the underlying substrate. The gate bottom dielectric layer located below the gate structure can block the leakage path between source/drain (S/D) regions, and thus the off-state drain-to-source leakage current (Isoff) can be reduced. Furthermore, the gate bottom dielectric layer sandwiched between the gate structure and the substrate can increase the distance between the metal gate structure and the well region in the substrate, and thus the capacitance between the gate structure and the well region can be reduced.

Moreover, the embodiments discussed herein further include an S/D bottom dielectric layer formed below the S/D region and between the S/D region and the underlying substrate. The S/D bottom dielectric layer located below the S/D region can isolate the S/D region from the underlying substrate, and thus the off-state drain-to-bulk leakage current (Iboff) can be reduced and Isoff can be reduced further. Furthermore, the capacitance between the S/D region and gate structure and the capacitance between the S/D region and the substrate can also be reduced. In addition, the provided structure with the gate and S/D bottom dielectric layers allows lowering anti-punch-through (APT) dosage or omitting the APT process. Therefore, the APT dosage out-diffusion impact can be eliminated, and thus the performance of threshold voltage (Vt) mismatch can be improved.

The various aspects of the present disclosure will now be described in more detail with reference to the figures. For avoidance of doubts, the X-direction, the Y-direction, and the Z-direction in the figures are perpendicular to one another and are used consistently. Throughout the present disclosure, like reference numerals denote like features unless otherwise indicated.

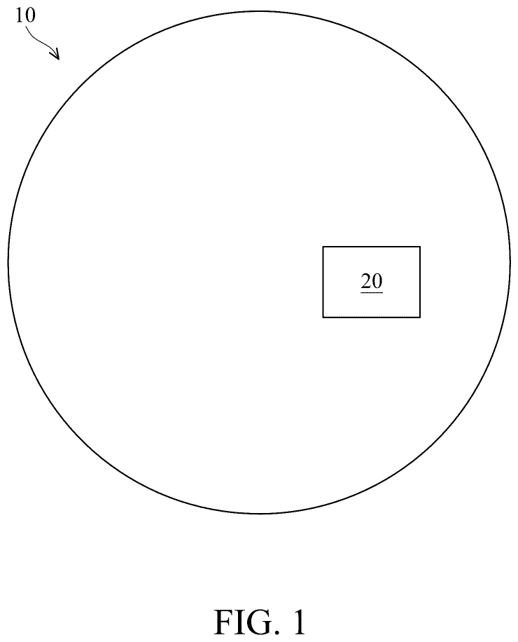

FIG. 1 is a fragmentary diagrammatic top view of an integrated circuit (IC) chip 10, in portion or entirety, in accordance with some embodiments. The IC chip 10 may include various passive microelectronic devices and active microelectronic devices, such as resistors, capacitors, inductors, diodes, p-type field effect transistors (PFETs), n-type field effect transistors (NFETs), metal-oxide semiconductor FETs (MOSFETs), complementary metal-oxide-semiconductor (CMOS) transistors, bipolar junction transistors (BJTs), laterally diffused MOS (LDMOS) transistors, high voltage transistors, high frequency transistors, other suitable components, or combinations thereof. The various microelectronic devices can be configured to provide the IC chip 10 with functionally distinct regions, such as a core region (also referred to as a logic region), a memory region (e.g., a static random access memory (SRAM) region), an analog region, a peripheral region (also referred to as an input/output (I/O) region), a dummy region, and/or other suitable regions.

As shown in FIG. 1, the IC chip 10 includes a logic region 20. In some embodiments, the logic region 20 includes an array of circuit cells having various logic cells or standard (STD) cells. The logic cells or STD cells may include transistors and interconnect structures that combine to provide a logic device and/or a logic function, such as an inverter, an AND, a NAND, an OR, an NOR, a NOT, an XOR, an XNOR, other suitable logic devices, or a combination thereof. In some embodiments, the logic region 20 can be replaced by a memory region. The memory region can include arrays of memory cells, each of which includes transistors and interconnection structures (also referred to as routing structures) that combine to provide a storage device and/or a storage function, such as a flip flop, a latch, another suitable memory device, or a combination thereof. In some embodiments, the memory region is configured with static random access memory (SRAM) cells, dynamic random-access memory (DRAM) cells, non-volatile random-access memory (NVRAM) cells, flash memory cells, other suitable memory cells, or a combination thereof. FIG. 1 has been simplified for the sake of clarity to better understand the inventive concepts of the present disclosure. Additional features can be added in the IC chip 10, and some of the features described herein can be replaced, modified, or eliminated in other embodiments of the IC chip 10.

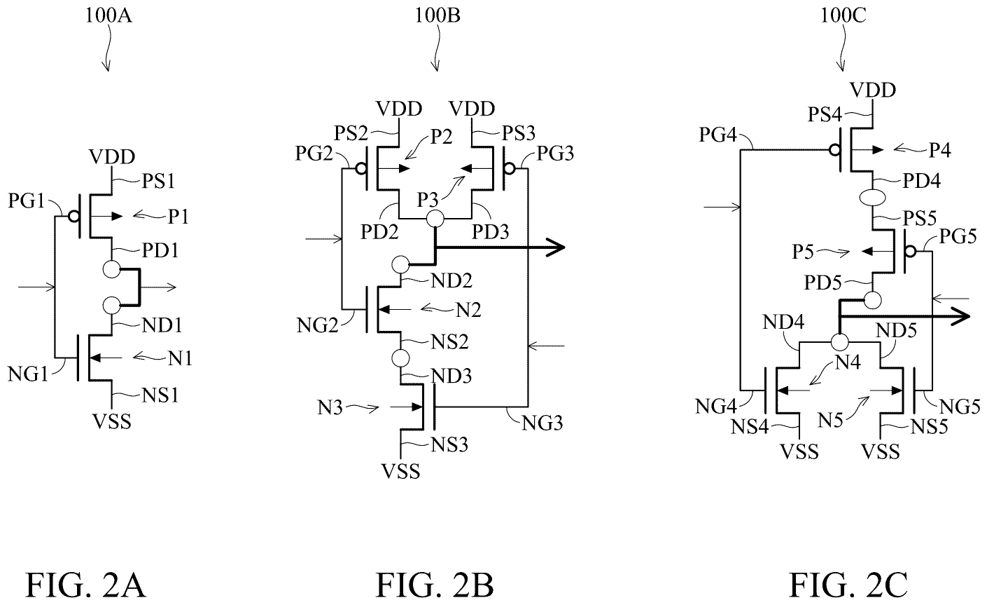

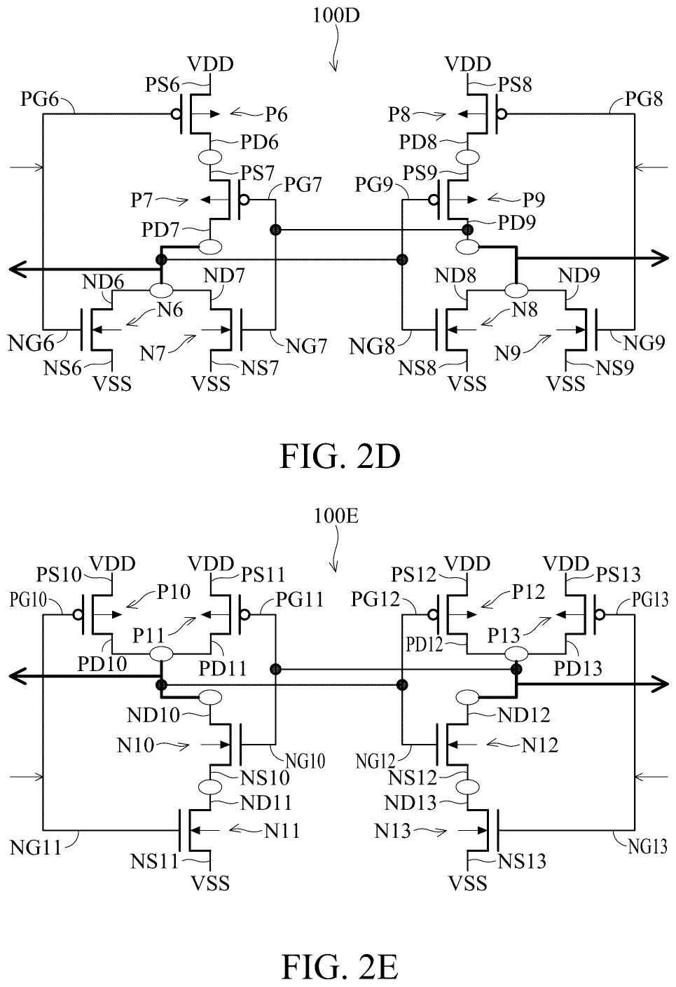

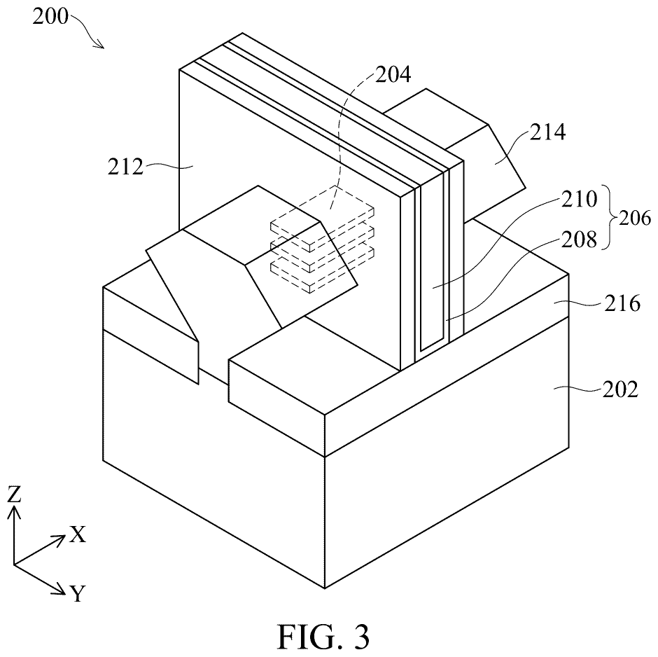

FIGS. 2A to 2E are circuit schematics of various STD cells in the array of circuit cells in the logic region 20 of the IC chip 10, in accordance with some embodiments. FIG. 2A illustrates an inverter 100A including an n-type transistor N1 and a P-type transistor P1. The n-type transistor N1 includes a source terminal NS1, a drain terminal ND1, and a gate terminal NG1. The P-type transistor P1 includes a source terminal PS1, a drain terminal PD1, and a gate terminal PG1.

As shown in FIG. 2A, the gate terminals NG1 and PG1 are coupled with each other to operate as an input terminal of the inverter 100A. The drain terminals ND1 and PD1 are coupled with each other to operate as an output terminal of the inverter 100A. The source terminal PS1 is coupled to a VDD voltage. The source terminal NS1 is coupled to a VSS voltage (or a ground voltage).

FIG. 2B illustrates a NAND (also referred to as a NAND logic gate, a NAND device or a NAND cell) 100B including n-type transistors N2, N3 and p-type transistors P2, P3. The n-type transistor N2 includes a source terminal NS2, a drain terminal ND2, and a gate terminal NG2, and the n-type transistor N3 includes a source terminal NS3, a drain terminal ND3, and a gate terminal NG3. The P-type transistor P2 includes a source terminal PS2, a drain terminal PD2, and a gate terminal PG2, and the P-type transistor P3 includes a source terminal PS3, a drain terminal PD3, and a gate terminal PG3.

As shown in FIG. 2B, the gate terminals NG2 and PG2 are coupled with each other to operate as a first input terminal of the NAND 100B. The gate terminals NG3 and PG3 are coupled with each other to operate as a second input terminal of the NAND 100B. The drain terminals ND2, PD2, and PD3 are coupled with each other to operate as an output terminal of the NAND 100B. In some embodiments, the connection of the drain terminals ND2, PD2, and PD3 are referred to as “common drain.” The source terminals PS2 and PS3 are coupled to the VDD voltage. The source terminal NS3 is coupled to the VSS voltage. The source terminal NS2 and drain terminal ND3 are coupled with each other.

FIG. 2C illustrates a NOR (also referred to as a NOR logic gate, a NOR device or a NOR cell) 100C including n-type transistors N4, N5 and P-type transistors P4, P5. The n-type transistor N4 includes a source terminal NS4, a drain terminal ND4, and a gate terminal NG4, and the n-type transistor N5 includes a source terminal NS5, a drain terminal ND5, and a gate terminal NG5. The P-type transistor P4 includes a source terminal PS4, a drain terminal PD4, and a gate terminal PG4, and the P-type transistor P5 includes a source terminal PS5, a drain terminal PD5, and a gate terminal PG5.

As shown in FIG. 2C, the gate terminals NG4 and PG4 are coupled with each other to operate as a first input terminal of the NOR 100C, and the gate terminals NG5 and PG5 are coupled with each other to operate as a second input terminal of the NOR 100C. The drain terminals ND4, ND5, and PD5 are coupled with each other to operate as an output terminal of the NOR 100C. In some embodiments, the connection of the drain terminals ND4, ND5, and PD5 are referred to as “common drain.” The source terminal PS4 is coupled to the VDD voltage. The source terminals NS4 and NS5 are coupled to VSS voltage. The source terminal PS5 and drain terminal PD4 are coupled with each other.

FIG. 2D illustrates a flip-flop (also referred to as a flip-flop device or a flip-flop cell) 100D including n-type transistors N6, N7, N8, N9 and P-type transistors P6, P7, P8, P9. The n-type transistor N6 includes a source terminal NS6, a drain terminal ND6, and a gate terminal NG6, and the n-type transistor N7 includes a source terminal NS7, a drain terminal ND7, and a gate terminal NG7. The n-type transistor N8 includes a source terminal NS8, a drain terminal ND8, and a gate terminal NG8, and the n-type transistor N9 includes a source terminal NS9, a drain terminal ND9, and a gate terminal NG9. The P-type transistor P6 includes a source terminal PS6, a drain terminal PD6, and a gate terminal PG6, and the P-type transistor P7 includes a source terminal PS7, a drain terminal PD7, and a gate terminal PG7. The P-type transistor P8 includes a source terminal PS8, a drain terminal PD8, and a gate terminal PG8, and the P-type transistor P9 includes a source terminal PS9, a drain terminal PD9, and a gate terminal PG9.

As shown in FIG. 2D, the flip-flop 100D is a set-reset (SR) NOR latch. The NOR latch may include a pair of cross-coupled NOR. Specifically, the output terminal of a first NOR is coupled to the second input terminal of a second NOR, and the output terminal of the second NOR is coupled to the second input terminal of the first NOR. The details of the other connections of the flip-flop 100D are similar to the NOR 100C, and may not be described in detail herein.

FIG. 2E illustrates a flip-flop 100E including n-type transistors N10, N11, N12, N13 and P-type transistors P10, P11, P12, P13. The n-type transistor N10 includes a source terminal NS10, a drain terminal ND10, and a gate terminal NG10, and the n-type transistor N11 includes a source terminal NS11, a drain terminal ND11, and a gate terminal NG11. The n-type transistor N12 includes a source terminal NS12, a drain terminal ND12, and a gate terminal NG12, and the n-type transistor N13 includes a source terminal NS13, a drain terminal ND13, and a gate terminal NG13. The P-type transistor P10 includes a source terminal PS10, a drain terminal PD10, and a gate terminal PG10, and the P-type transistor P11 includes a source terminal PS11, a drain terminal PD11, and a gate terminal PG11. The P-type transistor P12 includes a source terminal PS12, a drain terminal PD12, and a gate terminal PG12, and the P-type transistor P13 includes a source terminal PS13, a drain terminal PD13, and a gate terminal PG13.

As shown in FIG. 2E, the flip-flop 100E is a SR NAND latch. The NAND latch may include a pair of cross-coupled NAND. Specifically, the output terminal of a first NAND is coupled to the first input terminal of a second NAND, and the output terminal of the second NAND is coupled to the first input terminal of the first NAND. The details of the other connections of the flip-flop 100E are similar to the NAND 100B, and may not be described in detail herein.

Each of the circuit cells discussed above is constructed by transistors. The transistors may be planar transistors, fin field-effect transistor (FinFET) transistors, gate-all-around (GAA) transistors, nano-wire transistors, nano-sheet transistors, or a combination thereof. For the sake of providing an example, an exemplary GAA transistor is illustrated in FIG. 3. However, it should be understood that, the present disclosure should not be limited to a particular type of device, except as specifically claimed.

Referring to FIG. 3, a perspective view of an exemplary GAA transistor 200 is illustrated. The GAA transistor 200 is formed over a substrate 202. The substrate 202 may contains a semiconductor material, such as bulk silicon (Si). The GAA transistor 200 also includes one or more nanostructures 204 (dash lines) extending in the X-direction and vertically stacked (or arranged) in the Z-direction. More specifically, the nanostructures 204 are spaced apart from each other in the Z-direction. In some embodiments, the nanostructures 204 may also be referred to as channels, channel layers, nanosheets, or nanowires.

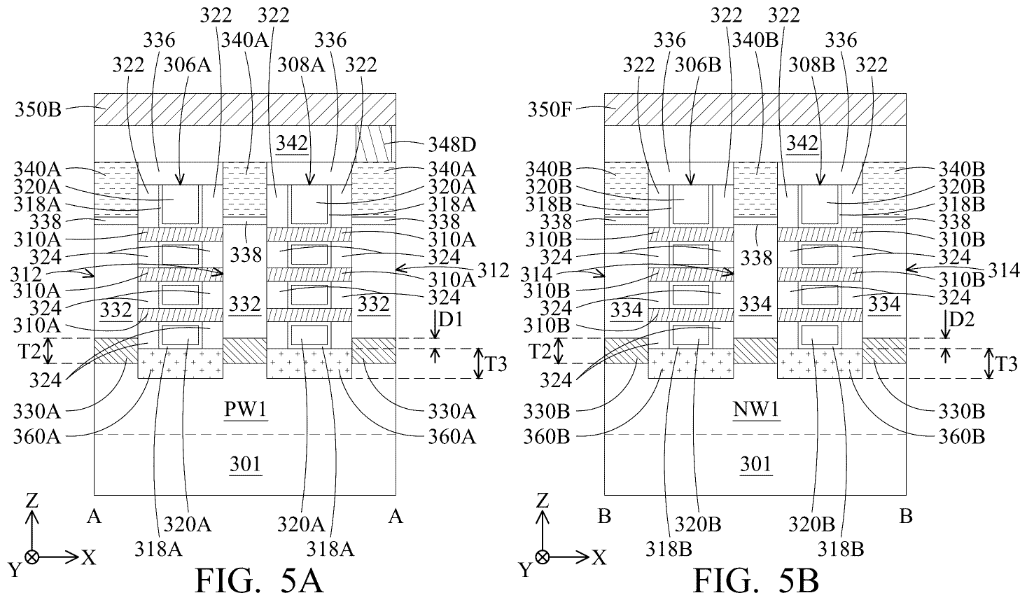

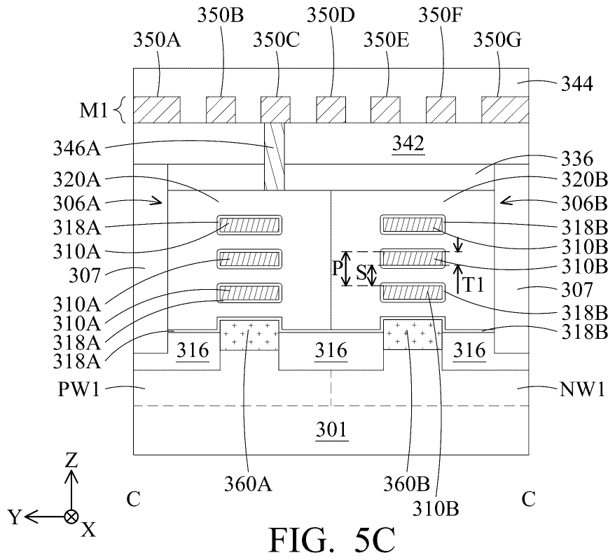

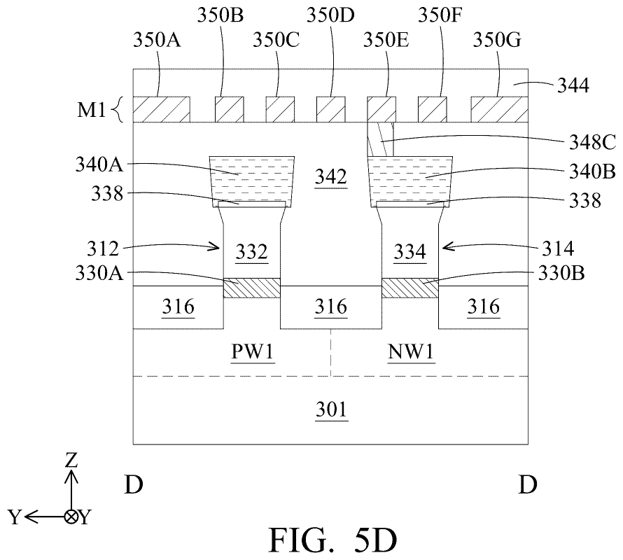

The GAA transistor 200 further includes a gate structure 206 including a gate dielectric layer 208 and a gate electrode 210. The gate dielectric layer 208 wraps around the nanostructures 204 and the gate electrode 210 wraps around the gate dielectric layer 208 (not shown in FIG. 3, may refer to FIGS. 5A to 5C). As shown in FIG. 3, gate spacers 212 are formed on sidewalls of the gate structure 206 and over the nanostructures 204.

The GAA transistor 200 further includes source/drain features 214. As shown in FIG. 3, two source/drain features 214 are on opposite sides of the gate structure 206. The nanostructures 204 extend in the X-direction to connect one source/drain feature 214 to the other source/drain feature 214. The source/drain features 214 may also be referred to as source/drain, or source/drain regions. In some embodiments, source/drain feature(s) may refer to a source or a drain, individually or collectively dependent upon the context.

The isolation structures 216 are formed over the substrate 202 and under the gate dielectric layer 208, the gate electrode 210, and the gate spacers 212. The isolation structures 216 are used for isolating the GAA transistor 200 from other devices. In some embodiments, the isolation structures 216 may include different structures, such as a shallow trench isolation (STI) structure or a deep trench isolation (DTI) structure. Therefore, the isolation structures 216 are also referred to as STI features or DTI features.

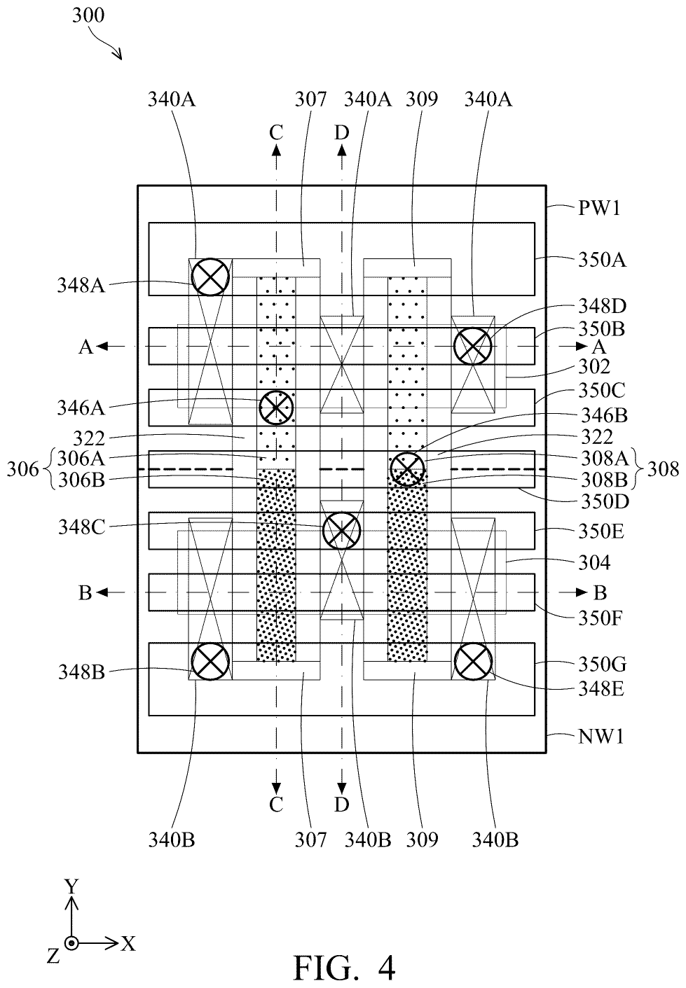

FIG. 4 illustrates a fragmentary diagrammatic top view (or layout) of a semiconductor structure 300 that may be disposed in the logic region 20 of the IC chip 10, in accordance with some embodiments of the present disclosure. FIG. 5A illustrates an X-Z cross-sectional view of the semiconductor structure 300 along line A-A in FIG. 4, and FIG. 5B illustrates an X-Z cross-sectional view of the semiconductor structure 300 along line B-B in FIG. 4, in accordance with some embodiments of the present disclosure. FIG. 5C illustrates a Y-Z cross-sectional view of the semiconductor structure 300 along line C-C in FIG. 4, and FIG. 5D illustrates a Y-Z cross-sectional view of the semiconductor structure 300 along line D-D in FIG. 4, in accordance with some embodiments of the present disclosure.

The semiconductor structure 300 may include CMOS devices, each of the CMOS devices includes an n-type MOSFET (NMOSFET) and a p-type MOSFET (PMOSFET). Each of the NMOSFET and the PMOSFET may be an embodiment of the GAA transistor 200. The semiconductor structure 300 may be used to constitute logic circuits or logic devices, such as inverters, NANDs, NORs, flip-flops, or the like. In the embodiment depicted in FIG. 4, the semiconductor structure 300 includes two CMOS devices that may constitute a NAND. It should be understood that, the embodiment depicted in FIG. 4 is merely an example. The present disclosure can be applied to other logic circuits, such as NORs, ANDs, ORs, flip-flops, or the like.

Referring to FIGS. 4 and 5A-5D, the semiconductor structure 300 includes an active region 302 and an active region 304 that extend lengthwise in the X-direction, in accordance with some embodiments. Each of the active regions 302 and 304 includes channel regions, source regions, and drain regions (where source regions and drain regions may be collectively referred to as source/drain regions herein) of transistors (e.g., the GAA transistor 200) of the semiconductor structure 300. The active region 302 may be disposed over a p-type well region (or P-Well) PW1, and the active region 304 may be disposed over an n-type well region (or N-Well) NW1.

The semiconductor structure 300 may include a common gate structure 306 including gate structures 306A, 306B and a common gate structure 308 including gate structures 308A, 308B. The common gate structures 306 and 308 extend substantially parallel to one another, extend lengthwise in the Y-direction perpendicular to the X-direction, and are separated from each other in the X-direction. The gate structures 306A and 308A are over respective channel regions in the active region 302 and between respective source/drain regions in the active region 302. The gate structures 306B and 308B are over respective channel regions in the active region 304 and between respective source/drain regions in the active region 304.

In some embodiments, the gate structure 306A is engaged with the gate structure 306B, and the gate structure 308A is engaged with the gate structure 308B. In other embodiments, the gate structure 306A is separated from the gate structure 306B by an isolation structure, and/or the gate structure 308A is separated from the gate structure 308B by an isolation structure.

The active regions 302, 304 and the gate structures 306A, 306B, 308A, 308B are configured to provide transistors. In some embodiments, the gate structure 306A and the gate structure 308A engage the active region 302 (e.g., nanostructures 310A and source/drain features 312 that will be described in more detailed below) to construct a first NMOSFET and a second NMOSFET, respectively. In some embodiments, the gate structure 306B and the gate structure 308B engage the active region 304 (e.g., nanostructures 310B and source/drain features 314 that will be described in more detailed below) to construct a first PMOSFET and a second PMOSFET. In some embodiments, the first NMOSFET and the first PMOSFET constitute a first CMOS device, and the second NMOSFET and the second PMOSFET constitute a second CMOS device. In some embodiments, the first CMOS device and the second CMOS device are interconnected with each other to form a NAND device as NAND 100B described above.

The semiconductor structure 300 may include a substrate 301, over which the various features are formed, such as the common gate structures 306 and 308, the nanostructures 310A and 310B, and the source/drain features 312 and 314. In some embodiments, the substrate 301 is a p-type substrate. The substrate 301 may contains a semiconductor material, such as bulk silicon (Si). In other embodiments, the substrate 301 may include other semiconductors, such as germanium (Ge), silicon germanium (SiGe), or a III-V semiconductor material. Example III-V semiconductor materials may include GaAs, InP, GaP, GaN, GaAsP, AlInAs, AlGaAs, GaInP, and InGaAs. Alternatively, the substrate 301 may be a semiconductor-on-insulator substrate, such as a silicon-on-insulator (SOI) substrate, a silicon germanium-on-insulator (SGOI) substrate, or a germanium-on-insulator (GOI) substrate. Semiconductor-on-insulator substrates may be fabricated using separation by implantation of oxygen (SIMOX), wafer bonding, and/or other suitable methods.

In some embodiments, the p-type well region PW1 and the n-type well region NW1 are formed in or on the substrate 301. In the embodiment depicted in FIGS. 4 and 5A-5D, the p-type well region PW1 is configured for n-type transistors, and the n-type well region NW1 is configured for p-type transistors. For example, the first NMOSFET constructed by the gate structure 306A and the active region 302 and the second NMOSFET constructed by the gate structure 308A and the active region 302 are formed on the p-type well region PW1. For example, the first PMOSFET constructed by the gate structure 306B and the active region 304 and the second PMOSFET constructed by the gate structure 308B and the active region 304 are formed on the n-type well region NW1. The p-type well region PW1 may be doped with p-type dopants, such as boron (B), indium (In), other p-type dopant, or a combination thereof. The n-type well region NW1 may be doped with n-type dopants, such as phosphorus (P), arsenic (As), other n-type dopant, or a combination thereof.

In some embodiments, the substrate 301 further includes other doped regions formed with a combination of p-type dopants and n-type dopants. The various n-type and p-type well regions can be formed directly on or in the substrate 301, for example, providing a p-well structure, an n-well structure, a dual-well structure, a raised structure, or combinations thereof. An ion implantation process, a diffusion process, and/or other suitable doping process may be performed to form the various wells.

Similar to the isolation structures 216 discussed above, the semiconductor structure 300 may further include isolation structures (or isolation features) 316. In some embodiments, the isolation structures 316 are over the substrate 301 and between the active regions 302 and 304. The isolation structures 316 also isolate the adjacent active regions (e.g., the active regions 302 and 304). The isolation structures 316 may include silicon oxide, silicon nitride, silicon oxynitride, other suitable isolation material (for example, including silicon, oxygen, nitrogen, carbon, or other suitable isolation constituent), or a combination thereof. The isolation structures 316 may include different structures, such as STI structures, DTI structures, and/or local oxidation of silicon (LOCOS) structures. In some embodiments, STI features include a multi-layer structure that fills the trenches, such as a silicon nitride comprising layer disposed over a thermal oxide comprising liner layer. In other embodiments, STI features include a dielectric layer disposed over a doped liner layer (including, for example, boron silicate glass (BSG) or phosphosilicate glass (PSG)). In certain embodiments, STI features include a bulk dielectric layer disposed over a liner dielectric layer, where the bulk dielectric layer and the liner dielectric layer include materials depending on design requirements.

In some embodiments, each transistor in the semiconductor structure 300 includes nanostructures that are similar to the nanostructures 204 discussed above. In some embodiments, the nanostructures 310A constituting vertical stacks are suspended over and arranged vertically over the p-type well region PW1 and in the active region 302, as shown in FIG. 5A. In some embodiments, the nanostructures 310B constituting vertical stacks are suspended over and arranged vertically over the n-type well region NW1 and in the active region 304, as shown in FIG. 5B. For the purpose of simplicity, the nanostructures 310A and 310B may be collectively referred to as nanostructures 310. In the depicted embodiments, three nanostructures 310 are vertically stacked (or vertically arranged) from each other in the Z-direction for one transistor. However, there may be another appropriate number of nanostructures in one transistor. For example, there may be from 2 to 10 nanostructures 310 in one transistor.

In some embodiments, the nanostructures 310 extend lengthwise in the X-direction (see FIGS. 5A and 5B) and widthwise in the Y-direction (see FIG. 5C). In some embodiments, each of the nanostructures 310 has a thickness T1 in the Z-direction, the thickness T1 is in a range from about 3 nm to about 10 nm, as shown in FIG. 5C. In some embodiments, nanostructures 310 are spaced apart from each other in the Z-direction by a spacing S in a range from about 3 nm to about 12 nm, as shown in FIG. 5C. In some embodiments, the nanostructures 310 has vertically a pitch P (P=T1+S) in the Z-direction, the pitch P is in a range from about 8 nm to about 20 nm.

The nanostructures 310 may include a semiconductor material, such as silicon, germanium, silicon carbide, silicon phosphide, gallium arsenide, gallium phosphide, indium phosphide, indium arsenide, and/or indium antimonide, silicon germanium (SiGe), SiPC, GaAsP, AlInAs, AlGaAs, GaInAs, GaInP, and/or GaInAsP. In some embodiments, the nanostructures 310A include silicon for n-type transistors. In some embodiments, the nanostructures 310B include silicon germanium for p-type transistors. In other embodiments, the nanostructures 310 are all made of silicon, and the type of the transistors depends on the work function metal layers that are wrapped around the nanostructures 310. In some embodiments, the nanostructures 310 are epitaxially grown using an epitaxial growth process such as vapor-phase epitaxy (VPE), metal-organic CVD (MOCVD), molecular beam epitaxy (MBE), although other deposition processes, such as chemical vapor deposition (CVD), low pressure CVD (LPCVD), plasma-enhanced CVD (PECVD), atomic layer deposition (ALD), ultrahigh vacuum CVD (UHVCVD), remote plasma CVD (RPCVD), a combination thereof, or the like, may also be utilized.

In some embodiments, the semiconductor structure 300 further includes gate end dielectrics 307 and gate end dielectrics 309. In some embodiments, the gate end dielectrics 307 and 309 are formed on the opposite sides of the common gate structure 306 and 308 in the Y direction, respectively, as shown in FIGS. 4 and 5C. In some embodiments, the gate end dielectrics 307 and 309 may include a dielectric material such as SiN, SiO₂, silicon carbide (SiC), silicon oxynitride (SiON), silicon oxycarbide (SiOC), SiCN, silicon oxycarbon nitride (SiOCN), ZrSiO₂, HfO₂, HfSiO₄, LaO, Al₂O₃, combinations thereof, or the like, although any suitable material may be used. The methods of forming gate end dielectrics 307 and 309 may include forming a gate isolation trench through the gate structure, depositing a dielectric material in the gate isolation trench, and then performing an etching process such as an anisotropic etching process, although any suitable processes may be used.

In some embodiments, the gate structure 306A wraps around each of the nanostructures 310A in the corresponding vertical stack, the gate structure 308A wraps around each of the nanostructures 310A in the corresponding vertical stack, the gate structure 306B wraps around each of the nanostructures 310B in the corresponding vertical stack, and the gate structure 308B wraps around each of the nanostructures 310B in the corresponding vertical stack.

In some embodiments, the gate structures 306A and 308A each has a gate dielectric layer 318A and a gate electrode layer 320A, as shown in FIGS. 5A and 5C. The gate dielectric layers 318A wrap around each of the nanostructures 310A, and the gate electrode layers 320A wrap around the gate dielectric layers 318A. In some embodiments, the gate structures 306B and 308B each has a gate dielectric layer 318B and a gate electrode layer 320B, as shown in FIGS. 5B and 5C. The gate dielectric layers 318B wrap around each of the nanostructures 310B, and the gate electrode layers 320B wrap around the gate dielectric layers 318B. In some embodiments, each of the gate structures 306A, 306B, 308A, 308B further includes an interfacial layer (such as SiO₂, HfSiO, SiON, or other suitable material layers) between the gate dielectric layer (e.g., gate dielectric layers 318A and 318B) and the nanostructures (e.g., nanostructures 310A and 310B).

In some embodiments, the gate dielectric layers 318A and 318B may include oxide with nitrogen doped dielectric material (initial layer) combined with metal content high-k dielectric material (k value (dielectric constant)>7.9). For example, the gate dielectric layers 318A and 318B may include hafnium oxide (HfO₂), which has a dielectric constant in a range from about 18 to about 40. Alternatively, the gate dielectric layers 318A and 318B may include other high-k dielectric materials, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfLaO, HfSiO, LaSiO, AlSiO, HfTaO, HfTiO, (Ba,Sr)TiO₃ (BST), Al₂O₃, Si₃N₄, oxynitrides (SiON), combinations thereof, or other suitable materials. The gate dielectric layers 318A and 318B may include the same or different material compositions.

In some embodiments, the gate dielectric layers 318A and 318B may be formed by chemical oxidation, thermal oxidation, CVD, physical vapor deposition (PVD), ALD, high-density plasma CVD (HDPCVD), MOCVD, RPCVD, PECVD, LPCVD, atomic layer CVD (ALCVD), atmospheric pressure CVD (APCVD), flowable CVD (FCVD), and/or other suitable methods. In some embodiments, each of the gate dielectric layers 318A and 318B has a thickness in a range from about 0.5 nm to about 3 nm.

In some embodiments, the gate electrode layers 320A are formed to wrap around the gate dielectric layers 318A and the center portions of the nanostructures 310A, as shown in FIGS. 5A and 5C. In some embodiments, the gate electrode layers 320B are formed to wrap around the gate dielectric layers 318B and the center portions of the nanostructures 310B, as shown in FIGS. 5B and 5C. In some embodiments, the gate electrode layers 320A may include one or more n-type work function metal layers for n-type transistors. In some embodiments, the n-type work function metal layer may include a material such as Ti, Al, Ag, Mn, Zr, TiAl, TiAlC, TaC, TaCN, TaSiN, TaAl, TaAlC, TiAlN, other suitable n-type work function materials, or a combination thereof. In some embodiments, the gate electrode layers 320B may include one or more p-type work function metal layers for p-type transistors. In some embodiments, the p-type work function metal layer may include a material such as such as TiN, TaN, Ru, Mo, Al, ZrSi₂, MoSi₂, TaSi₂, NiSi₂, WN, other suitable p-type work function materials, or a combination thereof. In other embodiments, the gate electrode layers 320A and the gate electrode layers 320B may include the same work function metal layer. The n-type work function metal layer and the p-type work function metal layer may be deposited utilizing CVD, PVD, ALD, HDPCVD, MOCVD, RPCVD, PECVD, LPCVD, ALCVD, APCVD, FCVD, or the like. However, any suitable materials and processes may be utilized to form the n-type work function metal layer and the p-type work function metal layer.

In some embodiments, each of the gate electrode layers 320A and 320B may include a single layer or alternatively a multi-layer structure. In some embodiments, each of the gate electrode layers 320A and 320B may further include a capping layer, a barrier layer, and a fill material. The capping layer may be formed adjacent to the gate dielectric layers 318A, 318B and may be formed from a metallic material such as TaN, Ti, TiAlN, TiAl, Pt, TaC, TaCN, TaSiN, Mn, Zr, TiN, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like.

The barrier layer may be formed adjacent the capping layer, and may be formed of a different material than the capping layer. For example, the barrier layer may be formed of one or more layers of a metallic material such as TiN, TaN, Ti, TiAlN, TiAl, Pt, TaC, TaCN, TaSiN, Mn, Zr, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. In some embodiments, the fill material may include a suitable conductive material, such as Al, W, and/or Cu. In some embodiments, the capping layer, the barrier layer, and the fill material may be deposited using a deposition process such as CVD, PVD, ALD, HDPCVD, MOCVD, RPCVD, PECVD, LPCVD, ALCVD, APCVD, FCVD, or the like, although any suitable deposition process may be used.

Similar to the gate spacers 212 discussed above, the semiconductor structure 300 may further include gate spacers 322 formed on sidewalls of the gate structures 306A, 306B, 308A, and 308B in the X-direction, and over the nanostructures 310 in the Z-direction, as shown in FIGS. 4, 5A, and 5B. Furthermore, the gate spacers 322 extend lengthwise in the Y-direction (e.g., parallel to the common gate structures 306 and 308), and are on opposite sides (or on opposite sidewalls) of the common gate structures 306 and 308 in the X-direction, as shown in FIG. 4. The gate spacers 322 are over the nanostructures 310 and on top sidewalls of the gate structures 306A, 306B, 308A, and 308B, and thus are also referred to as gate top spacers or top spacers. The gate spacers 322 may include one or more dielectric materials selected from a group consisting of Si₃N₄, SiO₂, SiC, SiOC, SION, SiOCN, carbon doped oxide, nitrogen doped oxide, porous oxide, air gap, or a combination thereof. In some embodiments, the gate spacers 322 may include a single layer or a multi-layer structure.

In some embodiments, the semiconductor structure 300 further includes inner spacers 324 on the sidewalls of the gate structures 306A, 306B, 308A, and 308B in the X-direction, and below the topmost nanostructures 310 and the gate spacers 322 in the Z-direction. Furthermore, the inner spacers 324 are laterally between source/drain features and gate structures, such as between the source/drain features 312 and the gate structures 306A and 308A, and between the source/drain features 314 and the gate structures 306B and 308B in the X-direction. The inner spacers 324 are also vertically between the adjacent nanostructures 310 and between the bottommost nanostructures 310 and the substrate 301 in the Z-direction.

In some embodiments, the inner spacers 324 may include one or more dielectric materials selected from a group consisting of Si₃N₄, SiO₂, SiC, SiOC, SiON, SiOCN, air gap, or combinations thereof. In some embodiments, the inner spacers 324 include a dielectric material having higher k value (dielectric constant) than the gate spacers 322. In other embodiments, the inner spacers 324 include a dielectric material having lower k value than the gate spacers 322.

In some embodiments, the gate spacers 322 have a thickness in the X-direction that is in a range from about 3 nm to about 15 nm, and the inner spacers 324 have a thickness in the X-direction that is in a range from about 2 nm to about 12 nm. In some embodiments, the thickness of the gate spacers 322 in the X-direction and the thickness of the inner spacers 324 in the X-direction are the same. In other embodiments, the thickness of the gate spacers 322 in the X-direction is greater than the thickness of the inner spacers 324 in the X-direction, and the difference between the thicknesses of the gate spacer 322 and the inner spacers 324 is in a range from about 0.5 nm to about 5 nm.

In some embodiments, the semiconductor structure 300 further includes the source/drain features 312 over the substrate 301 and in the source/drain regions of the active region 302, as shown in FIGS. 5A and 5D. More specifically, the source/drain features 312 are attached to the opposite sides of the nanostructures 310A, and the gate structures 306A and 308A are respectively between two source/drain features 312 in the X-direction. In some embodiments, the semiconductor structure 300 further includes the source/drain features 314 over the substrate 301 and in the source/drain regions of the active region 304, as shown in FIGS. 5B and 5D. Specifically, the source/drain features 314 are attached to the opposite sides of the nanostructures 310B, and the gate structures 306B and 308B are respectively between two source/drain features 314.

In some embodiments, each of the source/drain features 312 includes a bottom dielectric layer 330A over the p-type well region PW1 and an epitaxial layer 332 over the bottom dielectric layer 330A, such that the bottom dielectric layer 330A is between the epitaxial layer 332 and the p-type well region PW1, as shown in FIGS. 5A and 5D. In some embodiments, each of the source/drain features 314 includes a bottom dielectric layer 330B over the n-type well region NW1 and an epitaxial layer 334 over the bottom dielectric layer 330B, such that the bottom dielectric layer 330B is between the epitaxial layer 334 and the n-type well region NW1, as shown in FIGS. 5B and 5D.

In some embodiments, each of the bottom dielectric layers 330A and 330B may be a single dielectric layer or a multiple dielectric layers structure, and may include one or more dielectric materials, such as Si₃N₄, SiO₂, SiC, SiOC, SiON, SiOCN, carbon doped oxide, nitrogen doped oxide, porous oxide, or combinations thereof. In other embodiments, each of the bottom dielectric layers 330A and 330B includes high-k dielectric materials, such as HfO₂, TiO₂, HfZrO, Ta₂O₃, HfSiO₄, ZrO₂, ZrSiO₂, LaO, AIO, ZrO, TiO, Ta₂O₅, Y₂O₃, SrTiO₃ (STO), BaTiO₃ (BTO), BaZrO, HfLaO, HfSiO, LaSiO, AlSiO, HfTaO, HfTiO, (Ba,Sr)TiO₃ (BST), Al₂O₃, combinations thereof, or other suitable materials. In some embodiments, the bottom dielectric layers 330A and 330B may be formed using a deposition process such as CVD, PVD, ALD, HDPCVD, MOCVD, RPCVD, PECVD, LPCVD, ALCVD, APCVD, other suitable methods, or combinations thereof.

In some embodiments, the bottom dielectric layer 330A is in direct contact with the p-type well region PW1, and is vertically sandwiched between the p-type well region PW1 and the epitaxial layer 332 in the Z-direction, as shown in FIGS. 5A and 5D. In some embodiments, the bottom dielectric layer 330A has a top surface that is lower than a bottom surface of the bottommost nanostructures 310A. In some embodiments, the sidewalls of the bottom dielectric layer 330A are in partial contact with the sidewalls of the bottommost pairs of inner spacers 324, as shown in FIG. 5A.

In some embodiments, the bottom dielectric layer 330B is in direct contact with the n-type well region NW1, and is vertically sandwiched between the n-type well region NW1 and the epitaxial layer 334 in the Z-direction, as shown in FIGS. 5B and 5D. In some embodiments, the bottom dielectric layer 330B has a top surface that is lower than a bottom surface of the bottommost nanostructures 310B. In some embodiments, the sidewalls of the bottom dielectric layer 330B are in partial contact with the sidewalls of the bottommost pairs of inner spacers 324, as shown in FIG. 5B.

In some embodiments, the bottom dielectric layers 330A and 330B have a thickness T2 in the Z-direction, the thickness T2 is in a range from about 2 nm to about 20 nm. In some embodiments, the bottom dielectric layers 330A and 330B protrude from the isolation structures 316, such that the top surfaces of the bottom dielectric layers 330A and 330B are higher than the top surfaces of the isolation structures 316 in the Z-direction, as shown in FIG. 5D. Since the bottom dielectric layers 330A and 330B are formed below the epitaxial layers of the source/drain features, the bottom dielectric layers 330A and 330B may also be referred to as the source/drain bottom dielectric layers.

In some embodiments, the epitaxial layer 332 may be formed by using epitaxial growth process such as VPE, MOCVD, MBE, although other deposition processes, such as CVD, LPCVD, PECVD, ALD, UHVCVD, RPCVD, a combination thereof, or the like, may also be utilized. In some embodiments, the epitaxial layer 332 may include epitaxially-grown material selected from a group consisting of SiP, SiC, SiPC, SiAs, Si, or a combination thereof. In some embodiments, the epitaxial layer 332 is an n-type doped epitaxial layer, and the epitaxially-grown material of the epitaxial layer 332 may be doped with n-type dopants (e.g., P, As, other n-type dopant, or a combination thereof) and have a doping concentration in a range from about 2×10¹⁹/cm³ to about 3×10²¹/cm³.

In some embodiments, the epitaxial layer 334 may be formed by using epitaxial growth process such as VPE, MOCVD, MBE, although other deposition processes, such as CVD, LPCVD, PECVD, ALD, UHVCVD, RPCVD, a combination thereof, or the like, may also be utilized. In some embodiments, the epitaxial layer 334 may include epitaxially-grown material selected from a group consisting of boron-doped SiGe, boron-doped SiGeC, boron-doped Ge, boron-doped Si, boron and carbon doped SiGe, or a combination thereof. In some embodiments, the epitaxial layer 334 is a p-type doped epitaxial layer, and the epitaxially-grown material of the epitaxial layer 334 may be doped with p-type dopants (e.g., B, In, other p-type dopant, or a combination thereof) and have a doping concentration in a range from about 1×10¹⁹/cm³ to about 6×10²⁰/cm³. In some embodiments, one or more annealing processes may be performed to activate the dopants in the epitaxial layers 332 and 334. The annealing processes may include rapid thermal annealing (RTA) and/or laser annealing processes.

In some embodiments, the semiconductor structure 300 further includes bottom dielectric layers 360A and 360B formed over the substrate 301 and below the common gate structures 306 and 308 and the nanostructures 310. More specifically, the bottom dielectric layers 360A are formed over the substrate 301 (and over the p-type well region PW1 formed in the substrate 301), below the nanostructures 310A, and below the gate structures 306A and 308A in the Z-direction, as shown in FIGS. 5A and 5C. The bottom dielectric layers 360B are formed over the substrate 301 (and over the n-type well region NW1 formed in the substrate 301), below the nanostructures 310B, and below the gate structures 306B and 308B in the Z-direction, as shown in FIGS. 5B and 5C. Since the bottom dielectric layers 360A and 360B are formed below the gate structures, the bottom dielectric layers 360A and 360B may also be referred to as gate bottom dielectric layers.

In some embodiments, each of the bottom dielectric layers 360A and 360B may be a single dielectric layer or a multiple dielectric layers structure, and may include one or more dielectric materials, such as Si₃N₄, SiO₂, SiC, SiOC, SiON, SiOCN, carbon doped oxide, nitrogen doped oxide, porous oxide, or combinations thereof. In some embodiments, the bottom dielectric layers 360A and 360B may be formed using a deposition process such as CVD, PVD, ALD, HDPCVD, MOCVD, RPCVD, PECVD, LPCVD, ALCVD, APCVD, other suitable methods, or combinations thereof. In some embodiments, the material of the bottom dielectric layers 360A and 360B is different than the material of the bottom dielectric layers 330A and 330B. In other embodiments, the material of the bottom dielectric layers 360A and 360B is the same material as the material of the bottom dielectric layers 330A and 330B. In certain embodiments, the material of bottom dielectric layers 360A and 360B has the same composition as the material of bottom dielectric layers 330A and 330B, but has different elemental concentrations.

In some embodiments, the bottom dielectric layers 360A are in contact with the gate structures 306A and 308A. For example, the bottom dielectric layers 360A may be in contact with the gate dielectric layers 318A. In some embodiments, the bottom dielectric layers 360A are vertically sandwiched between the substrate 301 (e.g., the p-type well region PW1 formed in the substrate 301) and the gate structures 306A and 308A in the Z-direction, as shown in FIGS. 5A and 5C. In some embodiments, the bottom dielectric layers 360A separate the gate structures 306A and 308A from the substrate 301 (e.g., the p-type well region PW1 formed in the substrate 301) in the Z-direction.

In some embodiments, the bottom dielectric layers 360A are in contact with the inner spacers 324. For example, for the inner spacers 324 formed on the sidewalls of the gate structures 306A and 308A, the bottom dielectric layers 360A are in contact with the bottommost pairs of inner spacers 324. In some embodiments, the bottom dielectric layers 360A are below the inner spacers 324 and are sandwiched between the bottommost pairs of inner spacers 324 and the substrate 301 (e.g., the p-type well region PW1 formed in the substrate 301) in the Z-direction, as shown in FIG. 5A. In some embodiments, the bottom dielectric layers 360A separate the bottommost pairs of inner spacers 324 from the substrate 301 (e.g., the p-type well region PW1 formed in the substrate 301) in the Z-direction.

In some embodiments, the bottom dielectric layers 360A are in contact with and below the gate structures 306A and 308A and the inner spacers 324. That is, the bottom dielectric layers 360A laterally extend under the gate structures 306A and 308A and the bottommost pairs of inner spacers 324. In some embodiments, a portion of the top surface of the bottom dielectric layer 360A is in contact with and covered by the gate structure 306A or 308A, and the remaining portion of the top surface of the bottom dielectric layer 360A is in contact with and covered by the bottommost pair of inner spacers 324. In some embodiments, the bottom dielectric layers 360A are in contact with the bottom dielectric layers 330A that are between the epitaxial layers 332 and the substrate 301. In some embodiments, the bottom dielectric layers 330A contact the opposite sides of the respective bottom dielectric layers 360A in the X-direction.

In some embodiments, the bottom dielectric layers 360B are in contact with the gate structures 306B and 308B. For example, the bottom dielectric layers 360B may be in contact with the gate dielectric layers 318B. In some embodiments, the bottom dielectric layers 360B are vertically sandwiched between the substrate 301 (e.g., the n-type well region NW1 formed in the substrate 301) and the gate structures 306B and 308B in the Z-direction, as shown in FIGS. 5B and 5C. In some embodiments, the bottom dielectric layers 360B separate the gate structures 306B and 308B from the substrate 301 (e.g., the n-type well region NW1 formed in the substrate 301) in the Z-direction.

In some embodiments, the bottom dielectric layers 360B are in contact with the inner spacers 324. For example, for the inner spacers 324 formed on the sidewalls of the gate structures 306B and 308B, the bottom dielectric layers 360B are in contact with the bottommost pairs of inner spacers 324. In some embodiments, the bottom dielectric layers 360B are below the inner spacers 324 and are sandwiched between the bottommost pairs of inner spacers 324 and the substrate 301 (e.g., the n-type well region NW1 formed in the substrate 301) in the Z-direction, as shown in FIG. 5B. In some embodiments, the bottom dielectric layers 360B separate the bottommost pairs of inner spacers 324 from the substrate 301 (e.g., the n-type well region NW1 formed in the substrate 301) in the Z-direction.

In some embodiments, the bottom dielectric layers 360B are in contact with and below the gate structures 306B and 308B and the inner spacers 324. That is, the bottom dielectric layers 360B laterally extend under the gate structures 306B and 308B and the bottommost pairs of inner spacers 324. In some embodiments, a portion of the top surface of the bottom dielectric layer 360B is in contact with and covered by the gate structure 306B or 308B, and the remaining portion of the top surface of the bottom dielectric layer 360B is in contact with and covered by the bottommost pair of inner spacers 324. In some embodiments, the bottom dielectric layers 360B are in contact with the bottom dielectric layers 330B that are between the epitaxial layers 334 and the substrate 301. In some embodiments, the bottom dielectric layers 330B contact the opposite sides of the respective bottom dielectric layers 360B in the X-direction.

In some embodiments, the bottom dielectric layers 360A and 360B have a thickness T3 in the Z-direction, the thickness T3 is in a range from about 4 nm to about 30 nm. In some embodiments, the ratio of the thickness T3 of the bottom dielectric layers 360A and 360B to the thickness T2 of the bottom dielectric layers 330A and 330B (T3/T2) is in a range from about 1.1 to 3.0. If the ratio (T3/T2) is smaller than 1.1, the bottom dielectric layers 360A and 360B will be too thin to provide the same capacity of leakage current reduction and capacitance reduction as the ratio in the range from about 1.1 to 3.0. If the ratio (T3/T2) is greater than 3.0, the bottom dielectric layers 360A and 360B will be too thick, and thus the formation of the bottom dielectric layers 360A and 360B will become more difficult.

In some embodiments, the top surfaces of the bottom dielectric layer 330A are higher than the top surfaces of the bottom dielectric layers 360A by a distance D1 in the Z-direction, the distance D1 is in a range from about 1 nm to about 5 nm. In some embodiments, the top surfaces of the bottom dielectric layers 330B are higher than the top surfaces of the bottom dielectric layers 360B by a distance D2 in the Z-direction, the distance D2 is in a range from about 1 nm to about 5 nm.

In some embodiments, the sidewalls of the bottom dielectric layer 330A are in partial contact with the sidewalls of the bottommost pairs of inner spacers 324, and in partial contact with the sidewalls of the bottom dielectric layer 360A, as shown in FIG. 5A. In some embodiments, the sidewalls of the bottom dielectric layer 330B are in partial contact with the sidewalls of the bottommost pairs of inner spacers 324, and in partial contact with the sidewalls of the bottom dielectric layer 360B, as shown in FIG. 5B. In some embodiments, the bottom dielectric layers 360A and 360B protrude from the isolation structures 316, such that the top surfaces of the bottom dielectric layers 360A and 360B are higher than the top surfaces of the isolation structures 316 in the Z-direction, as shown in FIG. 5C.

As described above, the gate bottom dielectric layer located below the gate structure can block the leakage path between the source/drain regions. For example, the bottom dielectric layers 360A can block the leakage path below the gate structures 306A and 308A and between the source/drain features 312, and the bottom dielectric layers 360B can block the leakage path below the gate structures 306B and 308B and between the source/drain features 314. Therefore, the off-state drain-to-source leakage current (Isoff) can be reduced. Moreover, the bottom dielectric layers 360A and 360B can increase the distance between the gate structures 306/308 and the substrate 301, and thus the capacitance between the gate structures 306A/308A and the p-type well region PW1 and the capacitance between the gate structures 306B/308B and the n-type well region NW1 can be reduced.

As described above, the source/drain bottom dielectric layer located below the source/drain region can isolate the source/drain region from the underlying substrate. For example, the bottom dielectric layers 330A can isolate the epitaxial layers 332 of the source/drain features 312 from the substrate 301, and the bottom dielectric layers 330B can isolate the epitaxial layers 334 of the source/drain features 314 from the substrate 301. Therefore, the off-state drain-to-bulk leakage current (Iboff) can be reduced and the Isoff can be reduced further. Furthermore, the capacitance between the source/drain regions and gate structures and the capacitance between the source/drain regions and the substrate can also be reduced.

Moreover, the existence of the bottom dielectric layers 330A, 330B, 360A, and 360B can reduce the need for an APT process, so that the APT dosage can be decreased or the APT process can be omitted. Therefore, the APT dosage out-diffusion impact can be eliminated, and the performance of the threshold voltage (Vt) mismatch can be improved. In addition, the enlargement of the gate spacers (e.g., the gate spacers 322 that are thicker than the inner spacers 324) can increase the distance between the gate structures (e.g., gate structures 306A, 306B, 308A, and 308B) and the source/drain contacts (e.g., source/drain contacts 340A and 340B described in more detailed below), and thus the capacitance between the gate structures and the source/drain contacts can be reduced.

In some embodiments, the semiconductor structure 300 further includes gate top dielectrics 336 over the gate structures 306A, 306B, 308A, and 308B, as shown in FIGS. 5A-5C. In some embodiments, the gate top dielectrics 336 are also over the gate spacers 322. In some embodiments, the gate top dielectrics 336 may include dielectric materials, such as SiO₂, SiOC, SION, SiOCN, carbon doped oxide, nitrogen doped oxide, carbon and nitrogen doped oxide, metal oxide dielectric, Hf oxide (HfO₂), Ta oxide (Ta₂O₅), Ti oxide (TiO₂), Zr oxide (ZrO₂), Al oxide (Al₂O₃), Y oxide (Y₂O₃), multiple metal content oxide, and a combination thereof. In some embodiments, the gate top dielectrics 336 may each include a single layer or a multi-layer structure.

In some embodiments, the semiconductor structure 300 further includes source/drain contacts 340A and source/drain contacts 340B (may be collectively referred to as source/drain contacts 340) that extend in the Y-direction, as shown in FIGS. 4, 5A, 5B, and 5D. In some embodiments, the source/drain contacts 340A are over and electrically connected to the respective source/drain features 312. In some embodiments, two source/drain contacts 340A are on the opposite sides of the gate structure 306A, and two source/drain contacts 340A are on the opposite sides of the gate structure 308A. In some embodiments, the source/drain contacts 340B are over and electrically connected to the respective source/drain features 314. In some embodiments, two source/drain contacts 340B are on the opposite sides of the gate structure 306B, and two source/drain contacts 340B are on the opposite sides of the gate structure 308B.

Each of the source/drain contacts 340 may include a conductive material, such as Al, Cu, W, Co, Ru, Mo, Ti, Ta, Ru, Rh, Ir, Pt, TiN, TiAl, TiAlN, TaN, TaC, combinations thereof, or the like, and may be deposited using a deposition process such as sputtering, CVD, PVD, ALD, HDPCVD, MOCVD, RPCVD, PECVD, LPCVD, ALCVD, APCVD, FCVD, electroplating, electroless plating, or the like. However, any suitable materials and processes may be utilized to form source/drain contacts 340. In some embodiments, the source/drain contacts 340 may each include single conductive material layer or multiple conductive material layers.

In some embodiments, the top surfaces of the source/drain contacts 340 are substantially coplanar with the top surfaces of the gate top dielectrics 336. In the embodiments where the gate top dielectrics 336 are omitted, the top surfaces of the source/drain contacts 340 are substantially coplanar with the top surfaces of the gate structures (e.g., the gate structures 306A, 306B, 308A, and 308B). In other embodiments, the top surfaces of the source/drain contacts 340 are higher than the top surfaces of the gate top dielectrics 336.

In some embodiments, the semiconductor structure 300 further includes silicide layers 338, as shown in FIGS. 5A, 5B, and 5D. In some embodiments, the silicide layers 338 are between the source/drain features 312 and the source/drain contacts 340A, and between the source/drain features 314 and the source/drain contacts 340B. In some embodiments, the silicide layers 338 may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), or other suitable compounds.

In some embodiments, the semiconductor structure 300 further includes an inter-layer dielectric (ILD) layer 342, the ILD layer 342 is over the substrate 301, over the isolation structures 316, over the gate structures 306A/306B/308A/308B, between the source/drain features 312/314, and between the source/drain contacts 340A/340B, as shown in FIGS. 5A-5D. In some embodiments, the semiconductor structure 300 further includes an inter-metal dielectric (IMD) layer 344 that is over the ILD layer 342, the source/drain contacts 340, and the gate structures 306A/306B/308A/308B, as shown in FIGS. 5C-5D.

The ILD layer 342 and the IMD layer 344 may include a dielectric material including, for example, silicon oxide, silicon nitride, silicon oxynitride, TEOS-formed oxide, PSG, borophosphosilicate glass (BPSG), low-k dielectric material, other suitable dielectric material, or combinations thereof. Exemplary low-k dielectric materials include fluoride-doped silica glass (FSG), carbon doped silicon oxide, xerogel, aerogel, amorphous fluorinated carbon, parylene, BCB-based dielectric material, polyimide, other low-k dielectric material, or combinations thereof. In some embodiments, the ILD layer 342 and the IMD layer 344 are a dielectric layer that includes a low-k dielectric material (generally referred to as a low-k dielectric layer). The ILD layer 342 and the IMD layer 344 may include a multi-layer structure having multiple dielectric materials.

In some embodiments, the semiconductor structure 300 further includes gate vias 346A-346B, source/drain vias 348A-348E, and a metal layer M1, as shown in FIGS. 4 and 5A-5D. The gate vias 346A-346B and the source/drain vias 348A-348E are formed in the ILD layer 342, and the metal layer M1 is formed in the IMD layer 344. The materials of the gate vias 346A-346B, the source/drain vias 348A-348E, and the metal layer M1 are selected from a group consisting of Ti, TiN, Ta, TaN, TiAlN, WN, W, Co, Mo, Ru, Pt, Al, Cu, other conductive materials, or combinations thereof.

In some embodiments, the metal layer M1 includes metal conductors 350A-350G that extend in the X-direction, and are over and electrically connected to the respective gate structures and the respective source/drain contacts, as shown in FIGS. 4 and 5A-5D. For example, the gate via 346A is on the common gate structure 306 and the metal conductor 350C is on the gate via 346A, such that the metal conductor 350C is electrically coupled to the common gate structure 306 through the gate via 346A. For example, the gate via 346B is on the common gate structure 308 and the metal conductor 350D is on the gate via 346B, such that the metal conductor 350D is electrically coupled to the common gate structure 308 through the gate via 346B.

For example, the source/drain via 348A is on first one of the source/drain contacts 340A and the metal conductor 350A is on the source/drain via 348A, such that the metal conductor 350A is electrically coupled to the first one of the source/drain contacts 340A through the source/drain via 348A. For example, the source/drain via 348B is on first one of the source/drain contacts 340B and the metal conductor 350G is on the source/drain via 348B, such that the metal conductor 350G is electrically coupled to the first one of the source/drain contacts 340B through the source/drain via 348B. For example, the source/drain via 348C is on second one of the source/drain contacts 340B and the metal conductor 350E is on the source/drain via 348C, such that the metal conductor 350E is electrically coupled to the second one of the source/drain contacts 340B through the source/drain via 348C. For example, the source/drain via 348D is on third one of the source/drain contacts 340A and the metal conductor 350B is on the source/drain via 348D, such that the metal conductor 350B is electrically coupled to the third one of the source/drain contacts 340A through the source/drain via 348D. For example, the source/drain via 348E is on third one of the source/drain contacts 340B and the metal conductor 350G is on the source/drain via 348E, such that the metal conductor 350G is electrically coupled to the third one of the source/drain contacts 340B through the source/drain via 348E.

As described above, in some embodiments, the semiconductor structure 300 includes a first CMOS device and a second CMOS device that collectively form a NAND device. In these embodiments, the metal conductor 350A may be a low voltage power line, such as a VSS power line, and the metal conductor 350G may be a high voltage power line, such as a VDD power line. In these embodiments, the first one of the source/drain contacts 340A (i.e., a source terminal of first NMOSFET) is couple to the metal conductor 350A (i.e., the VSS power line) through the source/drain via 348A. The first one of the source/drain contacts 340B (i.e., a source terminal of first PMOSFET) and the third one of the source/drain contacts 340B (i.e., a source terminal of second PMOSFET) are couple to the metal conductor 350G (i.e., the VDD power line) through the source/drain via 348B and the source/drain via 348E, respectively. In these embodiments, the first and second NMOSFETs share the second one of the source/drain features 312 and the second one of the source/drain contacts 340A (i.e., a drain terminal of first NMOSFET and a source terminal of second NMOSFET). The first and second PMOSFETs share the second one of the source/drain features 314 and the second one of the source/drain contacts 340B (i.e., drain terminals of first and second PMOSFET) that is coupled to the third one of the source/drain contacts 340A (i.e., a drain terminal of second NMOSFET). The second one of the source/drain contacts 340B is coupled to the third one of the source/drain contacts 340A through the source/drain vias 348C-348D, metal layer M1, and other metal layer overlying the metal layer M1 (not shown).

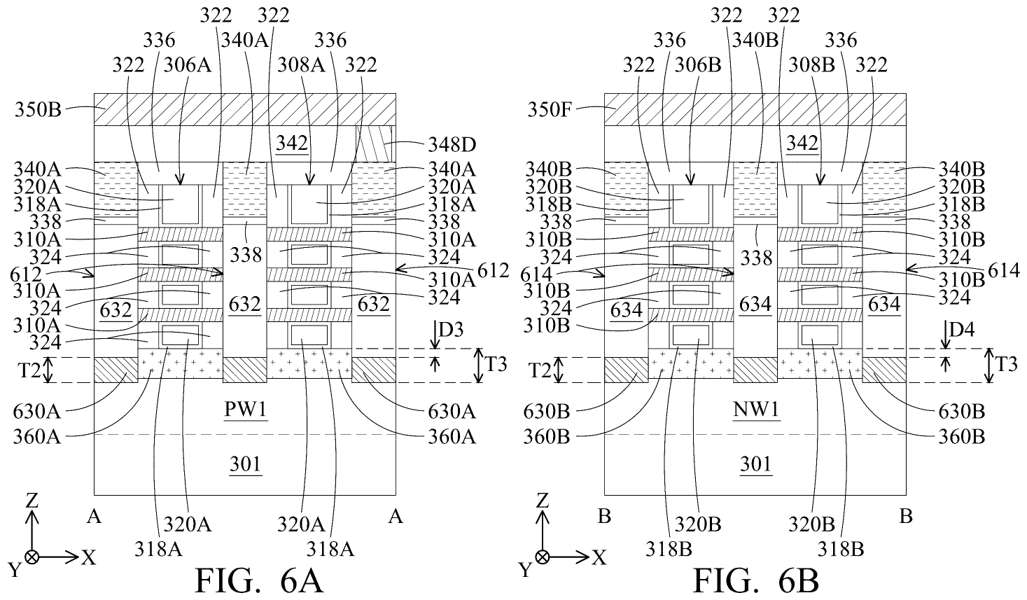

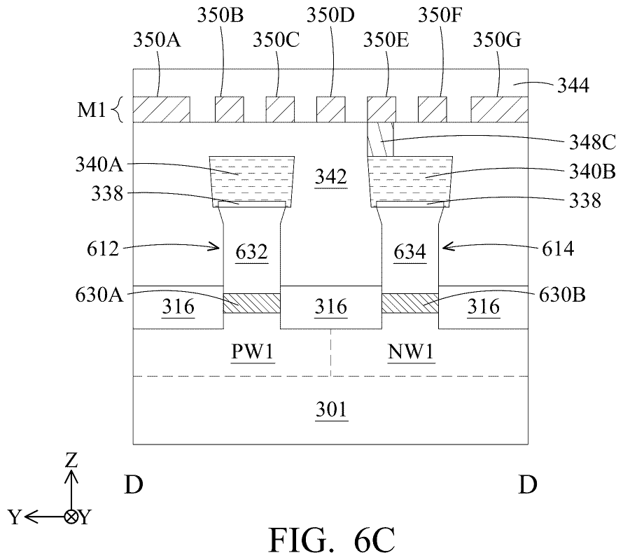

FIGS. 6A-6C are cross-sectional views of the semiconductor structure 300 in FIG. 4 to illustrate alternative embodiments of the semiconductor structure 300. FIGS. 6A, 6B, and 6C are taken along the lines A-A, B-B, and D-D in FIG. 4, respectively. The structure shown in FIGS. 6A-6C may be similar to the structure shown in FIGS. 5A-5D described above, except the source/drain features 312 and 314 shown in FIGS. 5A-5D are replaced by the source/drain features 612 and 614 shown in FIGS. 6A-6C.

In some embodiments, each of the source/drain features 612 includes a bottom dielectric layer 630A over the p-type well region PW1 and an epitaxial layer 632 over the bottom dielectric layer 630A, such that the bottom dielectric layer 630A is between the epitaxial layer 632 and the p-type well region PW1, as shown in FIGS. 6A and 6C. In some embodiments, each of the source/drain features 614 includes a bottom dielectric layer 630B over the p-type well region PW1 and an epitaxial layer 634 over the bottom dielectric layer 630B, such that the bottom dielectric layer 630B is between the epitaxial layer 634 and the n-type well region NW1, as shown in FIGS. 6B and 6C. In some embodiments, the method and material used in forming the bottom dielectric layers 630A and 630B are the same as or similar to those of the bottom dielectric layers 330A and 330B, and are not repeated herein. In some embodiments, the method and material used in forming the epitaxial layers 632 and 634 are the same as or similar to those of the epitaxial layers 332 and 334, and are not repeated herein.

In some embodiments, the bottom dielectric layer 630A is in direct contact with the p-type well region PW1, and is vertically sandwiched between the p-type well region PW1 and the epitaxial layer 632 in the Z-direction, as shown in FIGS. 6A and 6C. In some embodiments, the bottom dielectric layer 630A has a top surface that is lower than a bottom surface of the bottommost nanostructures 310A. In some embodiments, the bottom dielectric layers 630A contact the opposite sides of the respective bottom dielectric layers 360A in the X-direction.

In some embodiments, the top surfaces of the bottom dielectric layers 630A are lower than the top surfaces of the bottom dielectric layers 360A by a distance D3 in the Z-direction, the distance D3 is in a range from about 1 nm to about 5 nm, as shown in FIG. 6A. In some embodiments, the epitaxial layers 632 are in partial contact with the sidewalls of the bottom dielectric layer 360A. In some embodiments, the bottom surfaces of the bottom dielectric layers 630A are higher than the bottom surfaces of the bottom dielectric layers 360A, and the sidewalls of bottom dielectric layers 630A are fully covered by the sidewalls of the bottom dielectric layers 360A. In other embodiments, the bottom surfaces of the bottom dielectric layers 630A are lower than the bottom surfaces of the bottom dielectric layers 360A, and the sidewalls of the bottom dielectric layers 630A are in partial contact with the sidewalls of the bottom dielectric layers 360A.

In some embodiments, the bottom dielectric layer 630B is in direct contact with the n-type well region NW1, and is vertically sandwiched between the n-type well region NW1 and the epitaxial layer 634 in the Z-direction, as shown in FIGS. 6B and 6C. In some embodiments, the bottom dielectric layer 630B has a top surface that is lower than a bottom surface of the bottommost nanostructures 310B. In some embodiments, the bottom dielectric layers 630B contact the opposite sides of the respective bottom dielectric layers 360B in the X-direction.

In some embodiments, the top surfaces of the bottom dielectric layers 630B are lower than the top surfaces of the bottom dielectric layers 360B by a distance D4 in the Z-direction, the distance D4 is in a range from about 1 nm to about 5 nm, as shown in FIG. 6B. In some embodiments, the epitaxial layers 634 are in partial contact with the sidewalls of the bottom dielectric layer 360B. In some embodiments, the bottom surfaces of the bottom dielectric layers 630B are higher than the bottom surfaces of the bottom dielectric layers 360B, and the sidewalls of bottom dielectric layers 630B are fully covered by the sidewalls of the bottom dielectric layers 360B. In other embodiments, the bottom surfaces of the bottom dielectric layers 630B are lower than the bottom surfaces of the bottom dielectric layers 360B, and the sidewalls of the bottom dielectric layers 630B are in partial contact with the sidewalls of the bottom dielectric layers 360B.

In some embodiments, similar to the bottom dielectric layers 330A and 330B, the bottom dielectric layers 630A and 630B have the thickness T2 that is in a range from about 2 nm to about 20 nm. In some embodiments, the top surfaces of the bottom dielectric layers 630A and 630B are lower than the top surfaces of the isolation structures 316 in the Z-direction, as shown in FIG. 6C. Similar to the bottom dielectric layers 330A and 330B, the bottom dielectric layers 630A and 630B may also be referred to as the source/drain bottom dielectric layers.

In the embodiments where top surfaces of the source/drain bottom dielectric layers (e.g., the bottom dielectric layers 330A and 330B) are higher than top surfaces of the gate bottom dielectric layers (e.g., the bottom dielectric layers 360A and 360B) (see FIGS. 5A to 5D), it is benefit to the capacitance reduction. In these embodiments, the capacitance between the gate structures (e.g., the gate structures 306A, 308A, 306B, and 308B) and the source/drain features (e.g., the source/drain features 312 and 314) can be reduced further.

In the embodiments where top surfaces of the source/drain bottom dielectric layers (e.g., the bottom dielectric layers 630A and 630B) are lower than top surfaces of the gate bottom dielectric layers (e.g., the bottom dielectric layers 360A and 360B) (see FIGS. 6A to 6C), it is benefit to the source/drain growth. In these embodiments, since there is more space for growing the epitaxial layers (e.g., the epitaxial layers 632 and 634), it is easier to grow the epitaxial layers from the bottommost nanostructures (e.g., the bottommost nanostructures 310A and 310B).

In some embodiments, the NMOSFETs and PMOSFETs of the semiconductor structure 300 may include different source/drain structures. For example, the NMOSFETs may include source/drain features 312 including the bottom dielectric layers 330A, as shown in FIG. 5A, and the PMOSFETs may include source/drain features 614 including the bottom dielectric layers 630B, as shown in FIG. 6B. For the NMOSFETs, the top surfaces of the bottom dielectric layers 330A is higher than the top surfaces of the bottom dielectric layers 360A. For the PMOSFETs, the top surfaces of the bottom dielectric layers 630B is lower than the top surfaces of the bottom dielectric layers 360B. Therefore, the volume of the epitaxial layers 634 of the source/drain features 614 of the PMOSFETs is greater than the volume of the epitaxial layers 332 of the source/drain features 312 of the NMOSFETs. As such, the strain of the source/drain features 614 of the PMOSFETs can be enhanced, and thus the channel mobility and the DC performance (e.g., on-state current (Ion)) of the PMOSFETs can be improved.

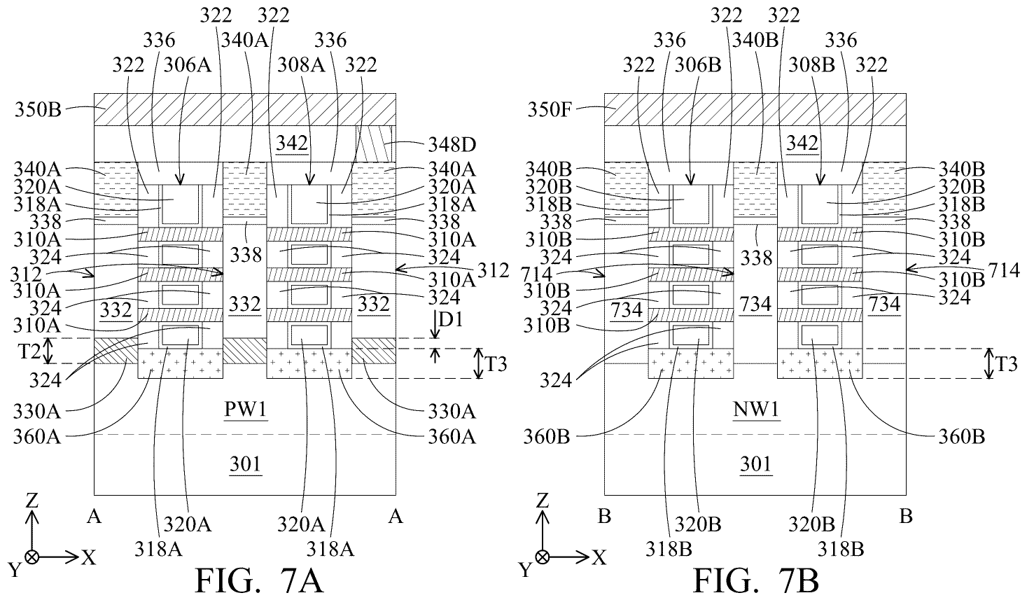

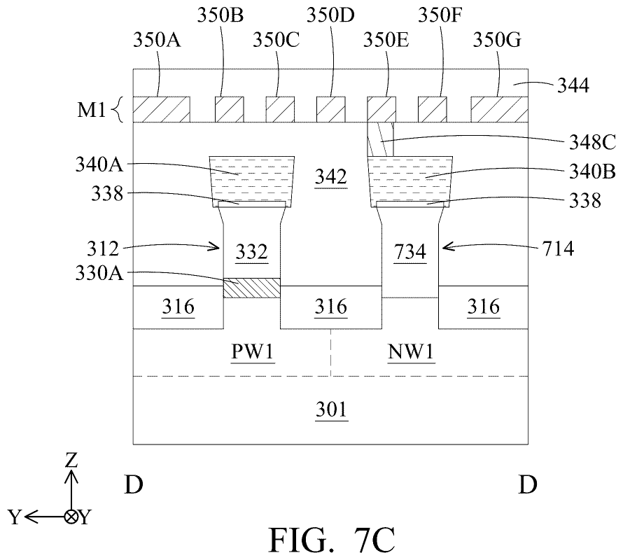

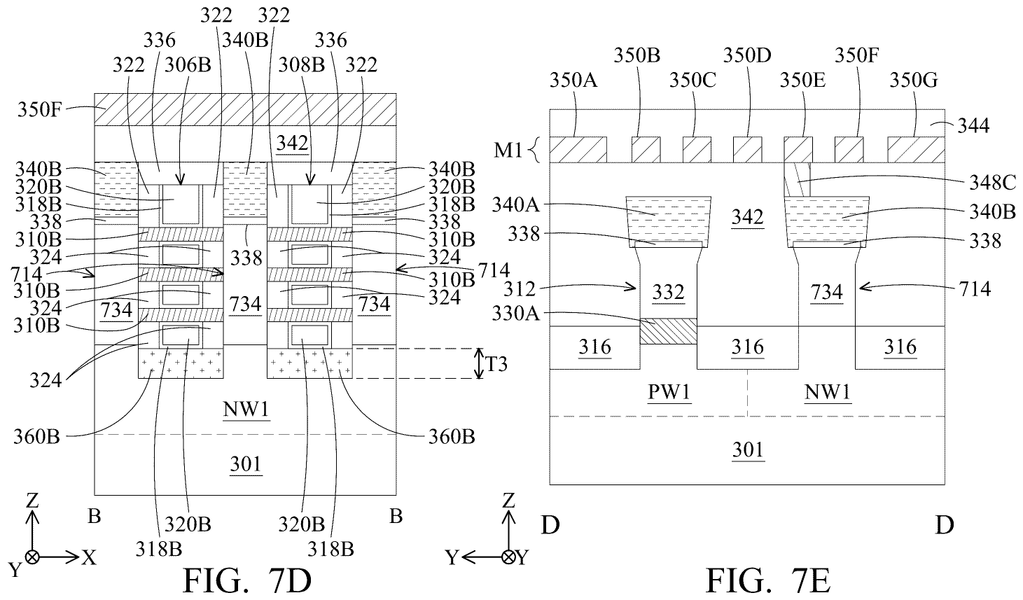

FIGS. 7A-7C are cross-sectional views of the semiconductor structure 300 in FIG. 4 to illustrate alternative embodiments of the semiconductor structure 300. FIGS. 7A, 7B, and 7C are taken along the lines A-A, B-B, and D-D in FIG. 4, respectively. The structure shown in FIGS. 7A-7C may be similar to the structure shown in FIGS. 5A-5D described above, except the source/drain features 314 shown in FIGS. 5A-5D are replaced by the source/drain features 714 shown in FIGS. 7A-7C. FIGS. 7D and 7E are cross-sectional views taken along lines B-B and D-D in FIG. 4, and illustrate alternative embodiments of FIGS. 7B and 7C, respectively.

In some embodiments, each of the source/drain features 714 includes an epitaxial layer 734 over the n-type well region NW1, as shown in FIGS. 7B and 7C. In some embodiments, compared with the source/drain features 314 shown in FIG. 5B, the bottom dielectric layers 330B are omitted from the source/drain features 714, such that the epitaxial layers 734 are in direct contact with the substrate 301 (and the n-type well region NW1 formed in the substrate 301), as shown in FIGS. 7B and 7C. In some embodiments, the bottom surfaces of the epitaxial layers 734 are lower than the top surfaces of the bottom dielectric layers 360B, so that the epitaxial layers 734 are in partial contact with the sidewalls of the bottom dielectric layers 360B.

In some embodiments, since the bottom surfaces of the epitaxial layers 734 are lower than the top surfaces of the bottom dielectric layers 360B, the volume of the epitaxial layers 734 of the PMOSFETs is greater than the volume of the epitaxial layers 332 of the NMOSFETs. In these embodiments, the strain of the source/drain features 714 of the PMOSFETs can be enhanced, and thus the channel mobility and the DC performance of the PMOSFETs can be improved. In some embodiments, the method and material used in forming the epitaxial layer 734 are the same as or similar to those of the epitaxial layer 334, and are not repeated herein.

In some embodiments, the bottom surfaces of the epitaxial layers 734 are level with or higher than the top surfaces of the bottom dielectric layers 360B, as shown in FIGS. 7D and 7E. In some embodiments, the bottom surfaces of the epitaxial layers 734 are level with or higher than the bottom surfaces of the bottom dielectric layers 330A. In further embodiments, the bottom surfaces of the epitaxial layers 734 are level with or higher than the top surfaces of the bottom dielectric layers 330A.

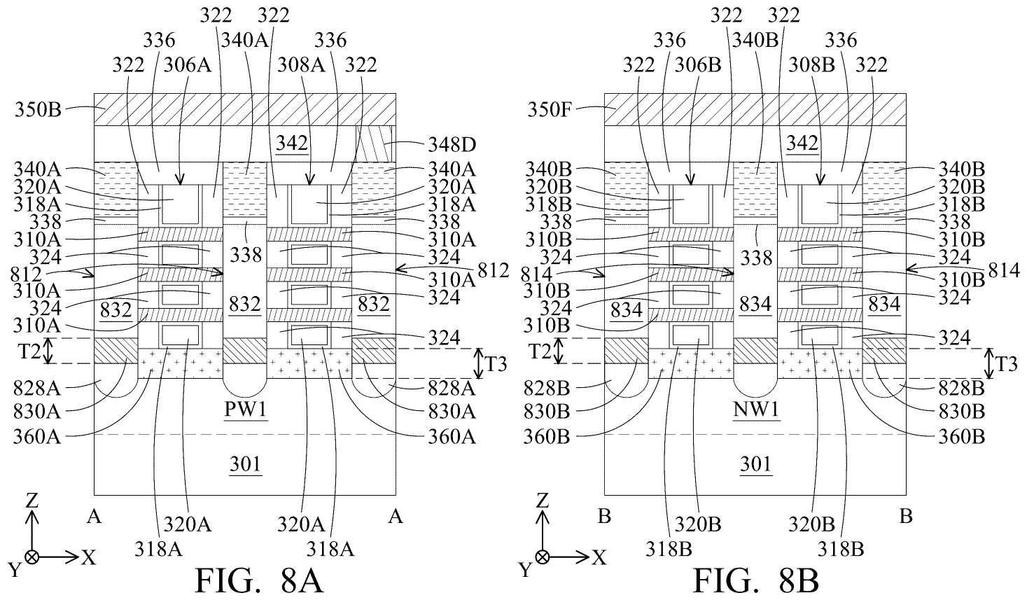

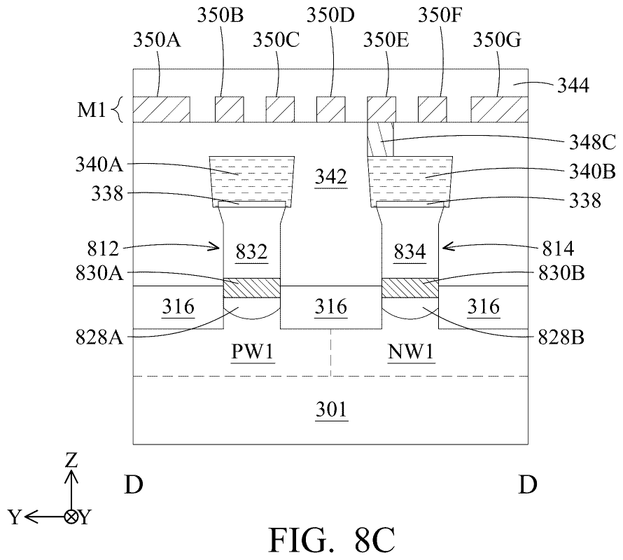

FIGS. 8A-8C are cross-sectional views of the semiconductor structure 300 in FIG. 4 to illustrate alternative embodiments of the semiconductor structure 300. FIGS. 8A, 8B, and 8C are taken along the lines A-A, B-B, and D-D in FIG. 4, respectively. The structure shown in FIGS. 8A-8C may be similar to the structure shown in FIGS. 5A-5D described above, except the source/drain features 312 and 314 shown in FIGS. 5A-5D are replaced by the source/drain features 812 and 814 shown in FIGS. 8A-8C.

In some embodiments, each of the source/drain features 812 includes an undoped epitaxial layer 828A over the p-type well region PW1, a bottom dielectric layer 830A over the undoped epitaxial layer 828A, and an epitaxial layer 832 over the bottom dielectric layer 830A, such that the bottom dielectric layer 830A and the undoped epitaxial layer 828A are between the epitaxial layer 832 and the p-type well region PW1, as shown in FIGS. 8A-8C. In some embodiments, the bottom dielectric layer 830A is sandwiched between the undoped epitaxial layer 828A and the epitaxial layer 832 in the Z-direction. In some embodiments, the materials and methods used in forming the bottom dielectric layers 830A and the epitaxial layers 832 are the same as or similar to those of the bottom dielectric layers 330A and the epitaxial layer 332, respectively, and are not repeated herein.

In some embodiments, each of the source/drain features 814 includes an undoped epitaxial layer 828B over the n-type well region NW1, a bottom dielectric layer 830B over the undoped epitaxial layer 828B, and an epitaxial layer 834 over the bottom dielectric layer 830B, such that the bottom dielectric layer 830B and the undoped epitaxial layer 828B are between the epitaxial layer 834 and the n-type well region NW1, as shown in FIGS. 8A-8C. In some embodiments, the bottom dielectric layer 830B is sandwiched between the undoped epitaxial layer 828B and the epitaxial layer 834 in the Z-direction. In some embodiments, the materials and methods used in forming the bottom dielectric layers 830B and the epitaxial layers 834 are the same as or similar to those of the bottom dielectric layers 330B and the epitaxial layer 334, respectively, and are not repeated herein. In some embodiments, similar to the bottom dielectric layers 330A and 330B, the bottom dielectric layers 830A and 830B have the thickness T2 that is in a range from about 2 nm to about 20 nm. Similar to the bottom dielectric layers 330A and 330B, the bottom dielectric layers 830A and 830B may also be referred to as the source/drain bottom dielectric layers.

In some embodiments, the undoped epitaxial layers 828A extend into and are in direct contact with the p-type well region PW1. In some embodiments, the undoped epitaxial layers 828B extend into and are in direct contact with the n-type well region NW1. In some embodiments, the undoped epitaxial layers 828A and 828B have a thickness T4 in the Z-direction, the thickness T4 is in a range from about 10 nm to about 60 nm. In some embodiments, the undoped epitaxial layers 828A and 828B are substantially free of dopants. The undoped epitaxial layers 828A and 828B may include silicon, germanium, silicon germanium, other suitable semiconductor materials, or combinations thereof. In some embodiments, the undoped epitaxial layers 828A and 828B include silicon that is substantially free of n-type dopants and p-type dopants. In some embodiments, the undoped epitaxial layers 828A and 828B are epitaxially grown using an epitaxial growth such as VPE, MOCVD, MBE, although other deposition processes, such as CVD, LPCVD, PECVD, ALD, UHVCVD, RPCVD, combinations thereof, or the like, may also be utilized.

In some embodiments, the positions of the bottom dielectric layer 830A and the epitaxial layer 832 are the same as or similar to the positions of the bottom dielectric layer 330A and the epitaxial layer 332, respectively. In these embodiments, the top surfaces of the bottom dielectric layers 830A are higher than the top surfaces of the bottom dielectric layers 360A by the distance D1 in the Z-direction. In these embodiments, the sidewalls of the bottom dielectric layer 830A are in partial contact with the sidewalls of the bottommost pairs of inner spacers 324, and in partial contact with the sidewalls of the bottom dielectric layer 360A, as shown in FIG. 8A. In some embodiments, the top surfaces of the bottom dielectric layers 830A are higher than the top surfaces of the isolation structures 316, as shown in FIG. 8C.

In some embodiments, the positions of the bottom dielectric layer 830B and the epitaxial layer 834 are the same as or similar to the positions of the bottom dielectric layer 330B and the epitaxial layer 334 shown in FIGS. 5A-5D, respectively. In these embodiments, the top surfaces of the bottom dielectric layers 830B are higher than the top surfaces of the bottom dielectric layers 360B by the distance D2 in the Z-direction. In these embodiments, the sidewalls of the bottom dielectric layer 830B are in partial contact with the sidewalls of the bottommost pairs of inner spacers 324, and in partial contact with the sidewalls of the bottom dielectric layer 360B, as shown in FIG. 8B. In some embodiments, the top surfaces of the bottom dielectric layers 830B are higher than the top surfaces of the isolation structures 316, as shown in FIG. 8C.

In other embodiments, the positions of the bottom dielectric layer 830A and the epitaxial layer 832 are the same as or similar to the positions of the bottom dielectric layer 630A and the epitaxial layer 632 shown in FIGS. 6A-6C, respectively. In these embodiments, the top surfaces of the bottom dielectric layers 830A are lower than the top surfaces of the bottom dielectric layers 360A by the distance D3 in the Z-direction (not shown in FIGS. 8A-8C). In these embodiments, the epitaxial layers 832 are in partial contact with the sidewalls of the bottom dielectric layers 360A (not shown in FIGS. 8A-8C). In the embodiments where the bottom surfaces of the bottom dielectric layers 830A is higher than the bottom surfaces of the bottom dielectric layers 360A, the sidewalls of bottom dielectric layers 830A are fully covered by the sidewalls of the bottom dielectric layers 360A (not shown in FIGS. 8A-8C). In the embodiments where the bottom surfaces of the bottom dielectric layers 830A is lower than the bottom surfaces of the bottom dielectric layers 360A, the sidewalls of bottom dielectric layers 830A are in partial contact with the sidewalls of the bottom dielectric layers 360A (not shown in FIGS. 8A-8C).

In other embodiments, the positions of the bottom dielectric layer 830B and the epitaxial layer 834 are the same as or similar to the positions of the bottom dielectric layer 630B and the epitaxial layer 634, respectively. In these embodiments, the top surfaces of the bottom dielectric layers 830B are lower than the top surfaces of the bottom dielectric layers 360B by the distance D4 in the Z-direction (not shown). In these embodiments, the epitaxial layers 834 are in partial contact with the sidewalls of the bottom dielectric layers 360B (not shown). In the embodiments where the bottom surfaces of the bottom dielectric layers 830B is higher than the bottom surfaces of the bottom dielectric layers 360B, the sidewalls of bottom dielectric layers 830B are fully covered by the sidewalls of the bottom dielectric layers 360B (not shown). In the embodiments where the bottom surfaces of the bottom dielectric layers 830B is lower than the bottom surfaces of the bottom dielectric layers 360B, the sidewalls of bottom dielectric layers 830B are in partial contact with the sidewalls of the bottom dielectric layers 360B (not shown).

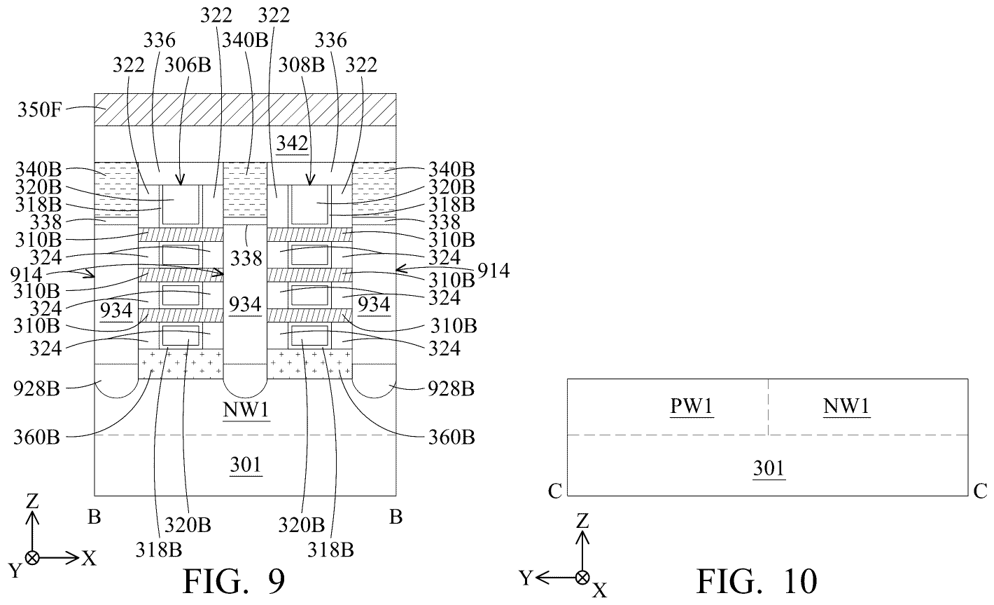

FIG. 9 is a cross-sectional view of the semiconductor structure 300 in FIG. 4 to illustrate alternative embodiments of the semiconductor structure 300. FIG. 9 is taken along line B-B in FIG. 4. The structure shown in FIG. 9 is similar to the structure shown in FIG. 5B described above, except the source/drain features 314 shown in FIG. 5B are replaced by the source/drain features 914 shown in FIG. 9.

In some embodiments, each of the source/drain features 914 includes an undoped epitaxial layer 928B over the n-type well region NW1 and an epitaxial layer 934 over the undoped epitaxial layer 928B, such that the undoped epitaxial layer 928B are between the epitaxial layer 934 and the n-type well region NW1 in the Z-direction, as shown in FIG. 9. In some embodiments, the materials and methods used in forming the undoped epitaxial layer 928B and the epitaxial layers 934 are the same as or similar to those of the undoped epitaxial layer 828B and the epitaxial layer 334, respectively, and are not repeated herein.

In some embodiments, the undoped epitaxial layers 928B extend into the n-type well region NW1. In some embodiments, the undoped epitaxial layers 928B are in direct contact with the epitaxial layers 934 and the n-type well region NW1. In some embodiments, the source/drain features 914 are free of a dielectric material between the undoped epitaxial layers 928B and the epitaxial layer 934. In some embodiments, the undoped epitaxial layers 928B have the thickness T4 in the Z-direction. In some embodiments, the top surface of the undoped epitaxial layer 928B is lower than the top surface of the bottom dielectric layer 360B. In these embodiments, the sidewalls of the bottom dielectric layer 360B are in partial contact with the sidewalls of the undoped epitaxial layers 928B and the epitaxial layers 934. In other embodiments, the top surface of the undoped epitaxial layer 928B is higher than the top surface of the bottom dielectric layer 360B. In these embodiments, the sidewalls of the bottom dielectric layer 360B are fully covered by the sidewalls of the undoped epitaxial layers 928B.

In some embodiments, as described above, the NMOSFETs and PMOSFETs of the semiconductor structure 300 may include different source/drain structures. For example, the NMOSFETs may include source/drain features 312, 612, or 812 (see FIG. 5A, 6A, 7A, or 8A), and the PMOSFETs may include source/drain features 314, 614, 714, 814, or 914 (see FIG. 5B, 6B, 7B, 8B, or 9).

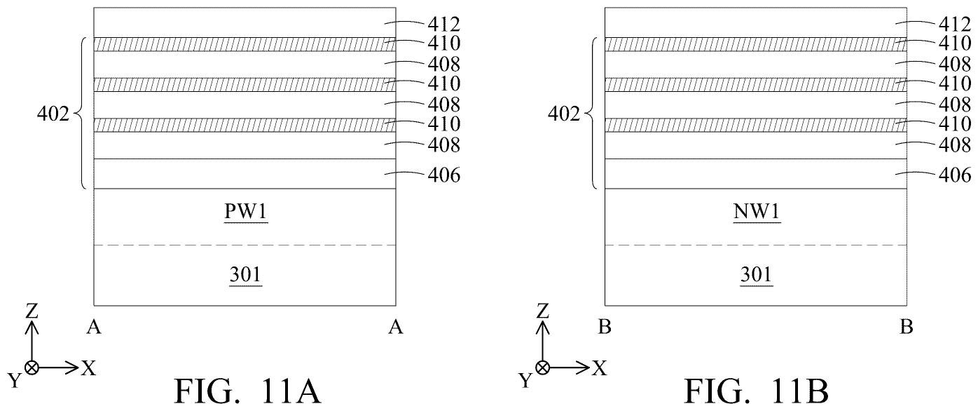

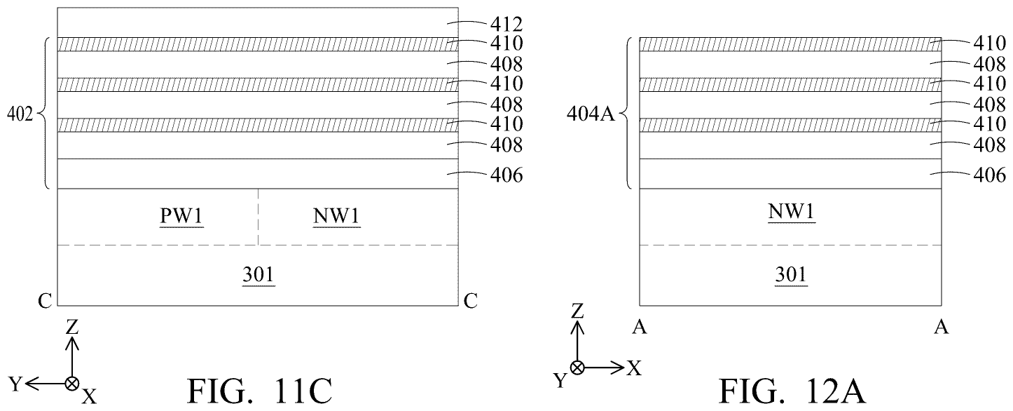

The following shows the formation of the semiconductor structure 300. FIGS. 11A to 23A are X-Z cross-sectional views of the semiconductor structure 300 at various fabrication stages along line A-A of FIG. 4, in accordance with some embodiments of the present disclosure. FIGS. 11B to 23B are X-Z cross-sectional views of the semiconductor structure 300 at various fabrication stages along line B-B of FIG. 4, in accordance with some embodiments of the present disclosure. FIGS. 10 and 11C to 23C are Y-Z cross-sectional views of the semiconductor structure 300 at various fabrication stages along line C-C of FIG. 4, in accordance with some embodiments of the present disclosure.

Referring to FIG. 10, the substrate 301 is provided. In some embodiments, the substrate 301 is lightly doped with a p-type or an n-type dopant. An anti-punch-through (APT) implantation may be performed on an upper portion of the substrate 301 to form an APT region (not shown). During the APT implantation, dopants may be implanted in the substrate 301. The dopants may have a conductivity type that is the opposite of the conductivity type of the source/drain regions (e.g., the source/drain features 312, 314, 612, 614, 714, 812, 814, and 914) that will be subsequently formed on the well regions (e.g., the p-type well region PW1 and the n-type well region NW1). The APT region may extend under the subsequently formed source/drain regions in the resulting NMOSFET and PMOSFET. As described above, the existence of the bottom dielectric layers (e.g., the bottom dielectric layers 330A, 330B, 360A, 360B, 630A, 630B, 830A, and 830B) can reduce the need for an APT process. Therefore, in some embodiments, the doping concentration of the APT implantation is reduced, alternatively, in other embodiments, the APT implantation is omitted.

In some embodiments, the p-type well region PW1 and the n-type well region NW1 are formed in or on the substrate 301, in accordance with some embodiments. In other embodiments, the substrate 301 may be formed to include other well regions, such as one or more other n-type well regions and/or p-type well regions. The materials and methods used in forming the substrate 301 and the various well regions (e.g., p-type well region PW1 and n-type well region NW1) have been discussed above, and are not repeated herein.

Referring to FIGS. 11A-11C, a stack 402 is formed over the substrate 301 (e.g., the p-type well region PW1 and the n-type well region NW1), in accordance with some embodiments. In some embodiments, the stack 402 includes a semiconductor layer 406, semiconductor layers 408, and semiconductor layers 410. In some embodiments, the semiconductor layer 406 is formed over the substrate 301, and the semiconductor layers 408 and the semiconductor layers 410 are alternatingly stacked over the semiconductor layer 406 in the Z-direction. The semiconductor layer 406, the semiconductor layers 408, and the semiconductor layers 410 may have different semiconductor compositions. In some embodiments, the semiconductor layer 406 and the semiconductor layers 408 are formed of SiGe, and the semiconductor layers 410 are formed of Si. In these embodiments, the additional germanium content in the semiconductor layer 406 and the semiconductor layers 408 allows selective removal or recess of the semiconductor layer 406 and the semiconductor layers 408 without substantial damages to the semiconductor layers 410. In some embodiments, the semiconductor layer 406 functions as a placeholder of the gate bottom dielectric layer that will be subsequently formed, and the semiconductor layers 408 are also referred to as sacrificial layers.

In some embodiments, the semiconductor layer 406 is Si₁₋ₓGeₓ, where x is in a range from about 0.35 to about 0.6, and the semiconductor layers 408 are Si_{1-y}Ge_{y}, where y is in a range from about 0.1 to about 0.35. That is, the Ge concentration of the semiconductor layer 406 is in a range from about 35% to about 60%, and the Ge concentration of the semiconductor layer 408 is in a range from about 10% to about 35%. In these embodiments, the different germanium contents in the semiconductor layer 406 and the semiconductor layers 408 allow selective removal or recess of the semiconductor layer 406 without substantial damages to the semiconductor layers 408. In some embodiments, the etching rate ratio of the semiconductor layer 406 and the semiconductor layer 408 is greater than 20:1. In some embodiments, the etching rate ratio of the semiconductor layer 408 and the semiconductor layer 410 is greater than 20:1.

In some embodiments, the semiconductor layer 406, the semiconductor layers 408, and the semiconductor layers 410 are epitaxially grown over or on the substrate 301 using an epitaxial growth such as VPE, MOCVD, MBE, although other deposition processes, such as CVD, LPCVD, PECVD, ALD, UHVCVD, RPCVD, a combination thereof, or the like, may also be utilized. The semiconductor layers 408 and the semiconductor layers 410 are deposited alternately, one-after-another, to form the stack. In some embodiments, the semiconductor layer 406 has a thickness in the Z-direction that is in a range from about 4 nm to about 30 nm. In some embodiments, each of the semiconductor layers 408 has a thickness in the Z-direction that is in a range from about 4 nm to about 15 nm.

For patterning purposes, the stack 402 may further include a hard mask layer 412 over the topmost semiconductor layer (e.g., the semiconductor layer 408 or 410). The hard mask layer 412 may be a single layer structure or a multi-layer structure. In some embodiments, the hard mask layer 412 is a single layer structure and includes a silicon germanium layer. In some embodiments, the hard mask layer 412 is a multi-layer structure and includes a silicon nitride layer and a silicon oxide layer over the silicon nitride layer. In other embodiments, the hard mask layer 412 is a multi-layer structure and includes a silicon germanium layer and a silicon layer over the silicon germanium layer.

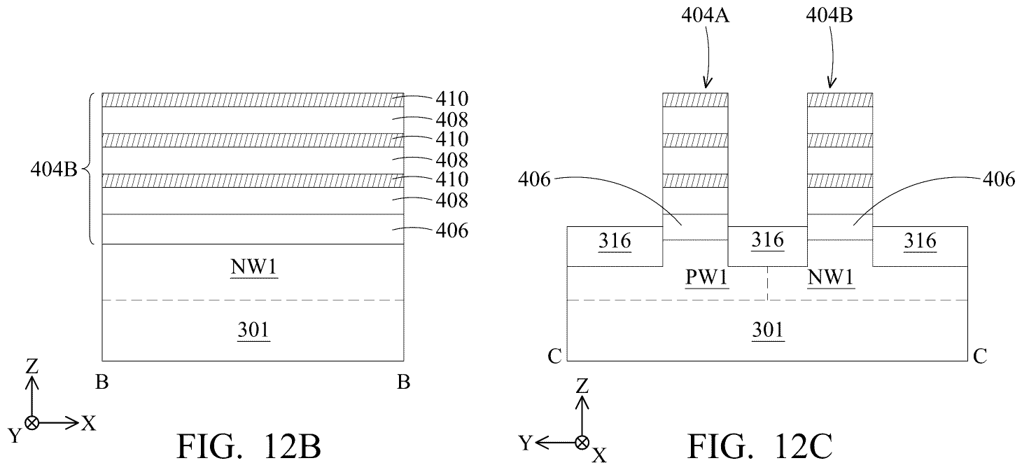

Referring to FIGS. 12A-12C, the substrate 301, the stack 402, and the hard mask layer 412 are then patterned to form a fin structure 404A and a fin structure 404B over the p-type well region PW1 and the n-type well region NW1, respectively, in accordance with some embodiments. The fin structures 404A and 404B may be included in the active region 302 and 304, respectively. Each of the fin structures 404A and 404B includes the semiconductor layer 406 and the semiconductor layers 408 and 410 that are alternately stacked over the semiconductor layer 406 in the Z-direction.

Still referring to FIGS. 12A-12C, the isolation structures 316 are formed over the substrate 301 and between the fin structures 404A and 404B, in accordance with some embodiments. After the fin structures 404A and 404B are formed, the hard mask layer 412 over the fin structures 404A and 404B is removed and the isolation structures 316 are formed over the substrate 301. In some embodiments, a dielectric material for the isolation structure 316 is first deposited. Specifically, the dielectric material is deposited to cover the fin structures 404A and 404B and the substrate 301. In various embodiments, the dielectric material may be deposited using a deposition process, such as CVD, subatmospheric CVD (SACVD), FCVD, ALD, spin-on coating, and/or other suitable process. The deposited dielectric material is then thinned and planarized, for example by a chemical mechanical polishing (CMP) process, until top surfaces of the hard mask layer 412 is exposed. The planarized dielectric material is further recessed by a dry etching process, a wet etching process, and/or a combination thereof to form the isolation structure 316.

In some embodiments, the semiconductor layers 406 in the fin structures 404A and 404B are surrounded by the isolation structures 316, as shown in FIG. 12C. In some embodiments, the top surfaces of the semiconductor layers 406 are higher than the top surfaces of the isolation structures 316. In other embodiments, the top surfaces of the semiconductor layers 406 are lower than the top surfaces of the isolation structures 316. In some embodiments, before the formation of the isolation structure 316, a liner layer may be conformally deposited over the substrate 301 using a deposition process, such as CVD, ALD, HDPCVD, MOCVD, RPCVD, PECVD, LPCVD, ALCVD, APCVD, FCVD, or combinations thereof. The material of the isolation structures 316 may include SiO₂, Si₃N₄, SION, FSG, combinations thereof, and/or other suitable materials. In some embodiments, the isolation structures 316 include a low-k dielectric material, such as those described herein.

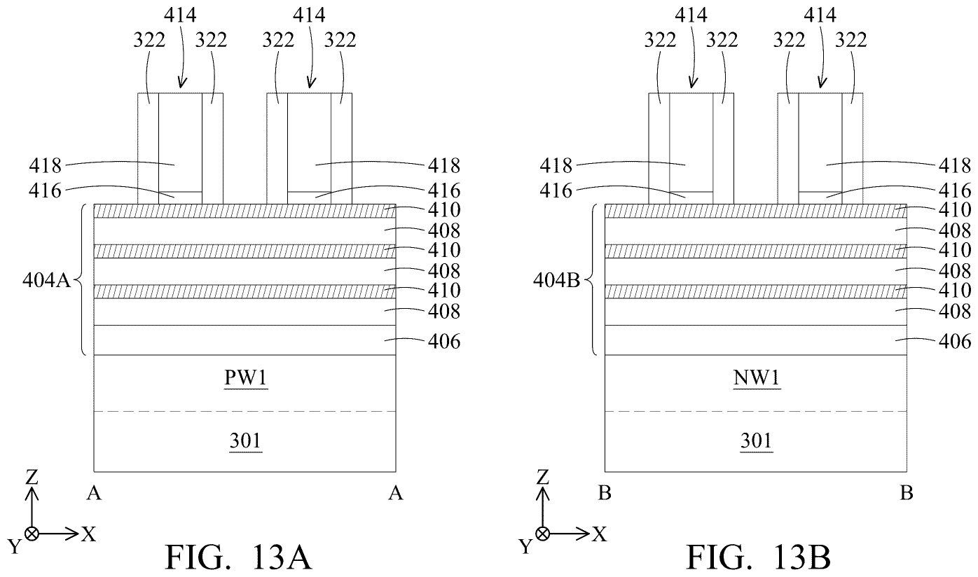

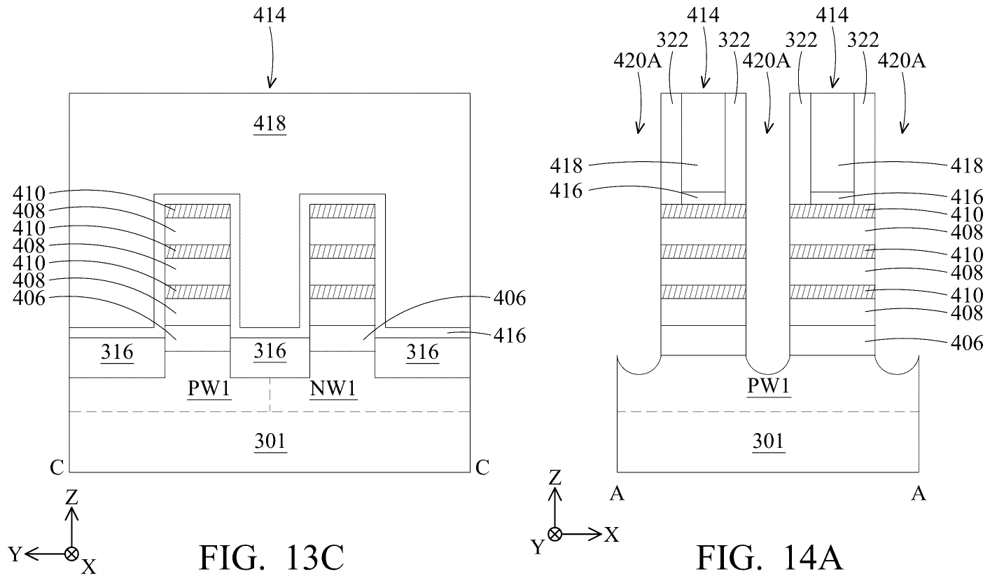

Referring to FIGS. 13A-13C, dummy gate structures 414 are formed over the fin structures 404A and 404B, in accordance with some embodiments. In some embodiments, to form the dummy gate structures 414, a dummy gate dielectric material for dummy gate dielectric layers 416 is first formed over the fin structures 404A and 404B. In some embodiments, the dummy gate dielectric layers 416 may include, for example, a dielectric material such as a nitride (e.g., SiN, SiON), a carbide (e.g., SiC), an oxide (e.g., SiO₂), or some other suitable material. Then, in some embodiments, a dummy gate electrode material for dummy gate electrodes 418 is formed over the dummy gate dielectric material. The dummy gate electrode material may include a conductive material selected from a group comprising of polysilicon, W, Al, Cu, AlCu, Ti, TiAlN, TaC, TaCN, TaSiN, Mn, Zr, TiN, Ta, TaN, Co, Ni, and/or a combination thereof. The dummy gate electrode material and/or the dummy gate dielectric material may be formed by way of a thermal oxidation process and/or a deposition process (e.g., PVD, CVD, PECVD, and ALD).

After the formation of the dummy gate dielectric material and the dummy gate electrode material, one or more etching processes may be performed to pattern the dummy gate electrode material for the dummy gate electrodes 418 and the dummy gate dielectric material for the dummy gate dielectric layers 416, thereby forming the dummy gate structures 414 each having the dummy gate dielectric layer 416 and the dummy gate electrode 418. The dummy gate structures 414 may undergo a gate replacement process through subsequent process to form metal gates (e.g., the gate structures 306A, 306B, 308A, and 308B), such as a high-k metal gate, as discussed in greater detail below.

Still referring to FIGS. 13A-13C, after forming the dummy gate structures 414, the gate spacers 322 are formed on sidewalls of the dummy gate structures 414 and over the top surfaces of the fin structures 404A and 404B. More specifically, the gate spacers 322 are formed on opposite sidewalls of the dummy gate structures 414. In some embodiments, the gate spacers 322 may be formed by conformally depositing a spacer layer (containing the dielectric material) over the fin structures 404A, 404B and the dummy gate structures 414, followed by an anisotropic etching process to remove top portions of the spacer layer from the top surfaces of the fin structures 404A, 404B and the dummy gate structures 414. After the anisotropic etching process, portions of the spacer layer on the sidewall surfaces of the fin structures 404A, 404B and the dummy gate structures 414 substantially remain and become the gate spacers 322. In some embodiments, the anisotropic etching process is a dry (e.g., plasma) etching process. Additionally or alternatively, the formation of the gate spacers 322 may also involve chemical oxidation, thermal oxidation, CVD, PVD, ALD, HDPCVD, MOCVD, RPCVD, PECVD, LPCVD, ALCVD, APCVD, FCVD, and/or other suitable methods. The material of the gate spacers 322 has been discussed above, and are not repeated herein.

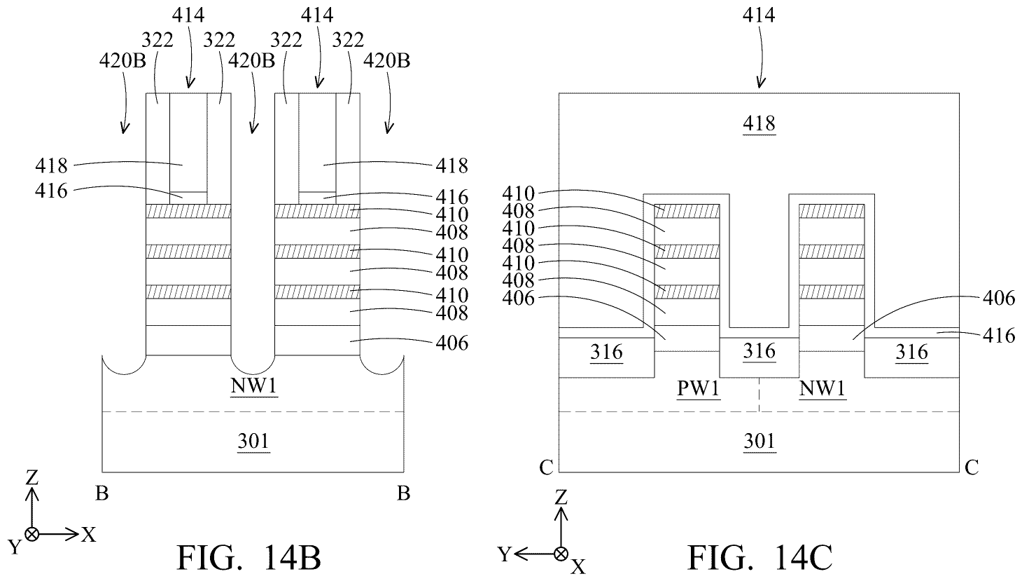

Referring to FIGS. 14A-14C, the fin structure 404A is recessed to form source/drain trenches 420A in the fin structure 404A, and the fin structure 404B is recessed to form source/drain trenches 420B in the fin structure 404B. In some embodiments, the source/drain trenches 420A and 420B are on opposite sides of the dummy gate structures 414. More specifically, the source/drain trenches 420A and 420B may be formed by performing one or more etching processes to remove portions of the semiconductor layers 406, the semiconductor layers 408, the semiconductor layers 410, and the substrate 301 that do not vertically overlap or be covered by the dummy gate structures 414 and the gate spacers 322. In some embodiments, a single etchant may be used to remove the semiconductor layers 406, the semiconductor layers 408, the semiconductor layers 410, and the substrate 301. In other embodiments, multiple etchants may be used to perform the etching process.

In some embodiments, portions of the substrate 301 are etched, as shown in FIGS. 14A and 14B. In other words, the source/drain trenches 420A and 420B extend into the substrate 301 (i.e., into the p-type well region PW1 and the n-type well region NW1, respectively), so that the bottom surfaces of the source/drain trenches 420A and 420B are lower than the topmost surfaces of the substrate 301. In some embodiments, the source/drain trenches 420A and 420B extend into the substrate 301 by a depth that is in a range from about 3 nm to about 30 nm.

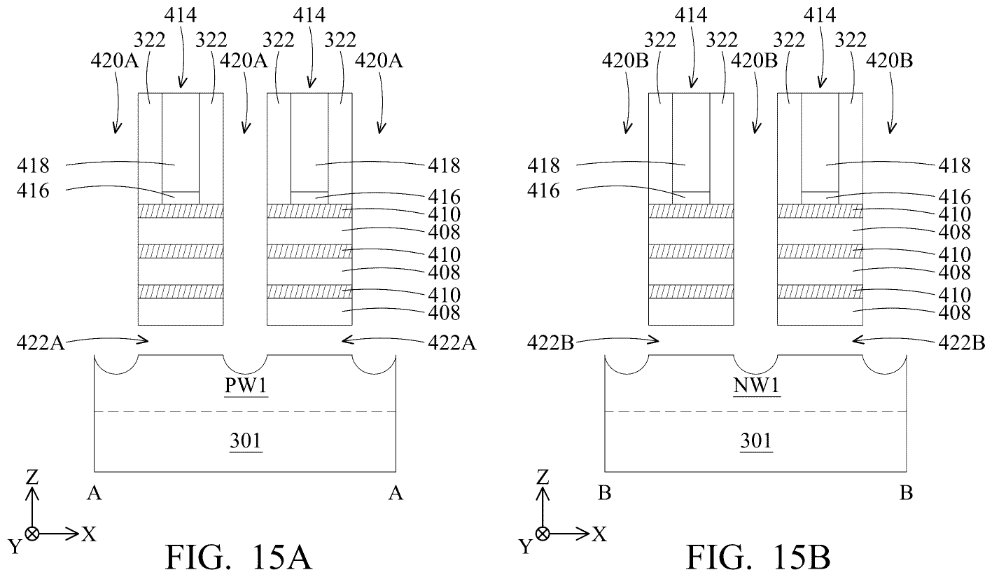

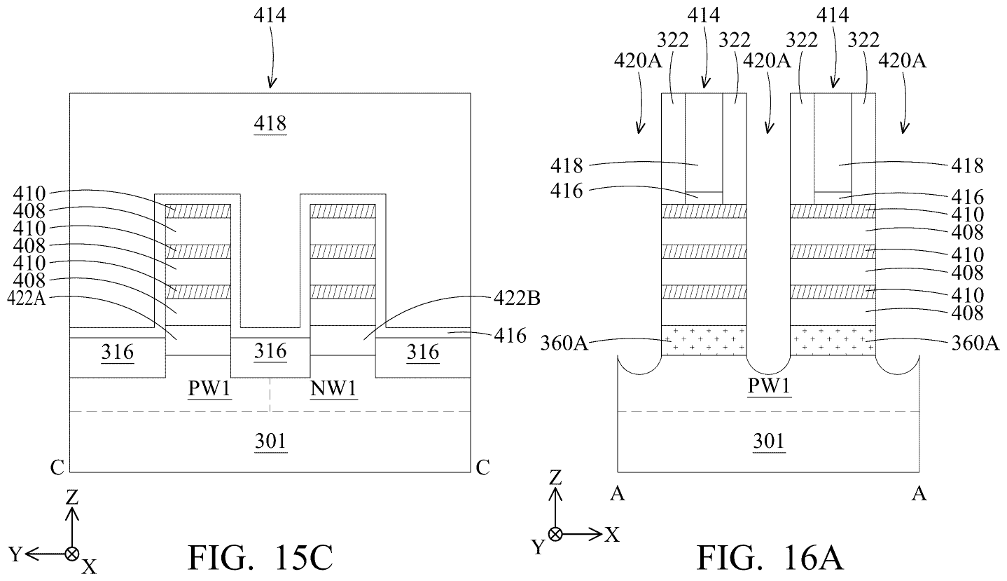

Referring to FIGS. 15A-15C, the semiconductor layers 406 exposed in the source/drain trenches 420A and 420B are removed by a selective etching process, in accordance with some embodiments. More specifically, the selective etching process is performed that selectively etches the semiconductor layers 406 through the source/drain trenches 420A and 420B, with minimal etching (or substantially no etching) of the semiconductor layers 408 and the semiconductor layers 410. After the selective etching process, in the fin structure 404A, recesses 422A are formed under the dummy gate structures 414, between the source/drain trenches 420A, and between the bottommost semiconductor layers 408 and the substrate 301 (e.g., the p-type well region PW1). After the selective etching process, in the fin structure 404B, recesses 422B are formed under the dummy gate structures 414, between the source/drain trenches 420B, and between the bottommost semiconductor layers 408 and the substrate 301 (e.g., the n-type well region NW1). The selective etching process is configured to laterally etch (e.g., along the X-direction) the semiconductor layers 406. The selective etching process may be a dry etching process, a wet etching process, other suitable etching process, or combinations thereof.

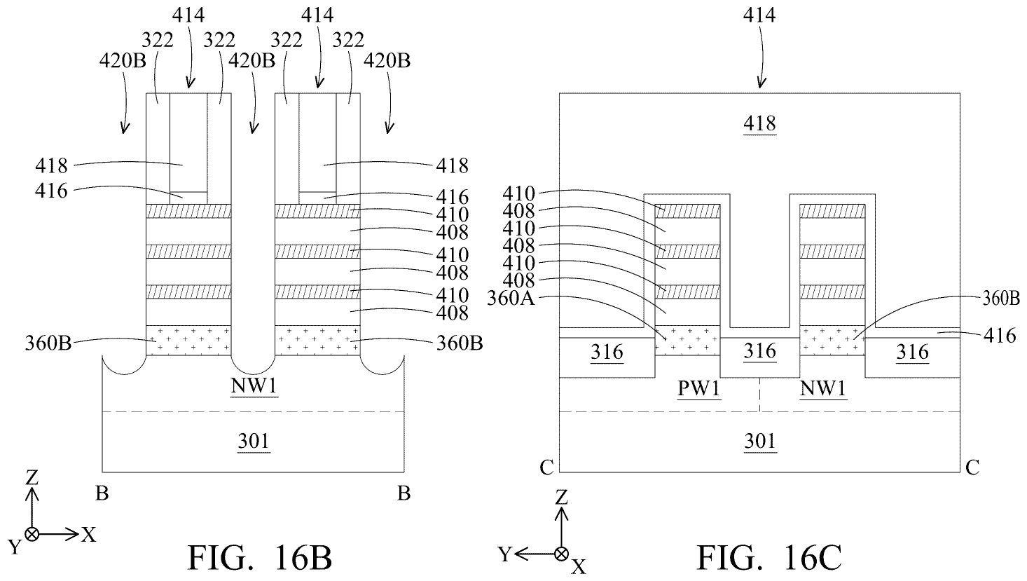

Referring to FIGS. 16A-16C, the bottom dielectric layers 360A are formed in the recesses 422A to fill the recesses 422A, and the bottom dielectric layers 360B are formed in the recesses 422B to fill the recesses 422B, in accordance with some embodiments. In some embodiments, sidewalls of the bottom dielectric layers 360A and 360B are aligned to the sidewalls of the gate spacers 322, the semiconductor layers 408, and the semiconductor layers 410. In other embodiments, sidewalls of the bottom dielectric layers 360A and 360B are aligned to the sidewalls of the dummy gate electrodes 418.

In order to form the bottom dielectric layers 360A and 360B, a deposition process is performed to form a dielectric material layer into the source/drain trenches 420A and 420B and the recesses 422A and 422B. For example, the deposition process may be CVD, PVD, ALD, HDPCVD, MOCVD, RPCVD, PECVD, LPCVD, ALCVD, APCVD, other suitable methods, or combinations thereof. The dielectric material layer partially (and, in some embodiments, completely) fills the source/drain trenches 420A and 420B. The deposition process is configured to ensure that the dielectric material layer fills the recesses 422A and 422B between the bottommost semiconductor layers 408 and the substrate 301 under the dummy gate structures 414. An etching back process is then performed that selectively etches the dielectric material layer to form bottom dielectric layers 360A and 360B with minimal etching (or substantially no etching) of the semiconductor layers 408, the semiconductor layers 410, the substrate 301, the dummy gate structures 414, and the gate spacers 322. The material and the dimension of the bottom dielectric layers 360A and 360B have been discussed above, and are not repeated herein.

In other embodiments, the etching back process is configured to selectively etch the dielectric material layer and remain less material layer. In these embodiments, after the etching back process, the remaining dielectric material layer partially fills the recesses 422A and 422B and forms bottom dielectric layers that are smaller than the bottom dielectric layers 360A and 360B in the X-direction. In these embodiments, there are still small recesses remained between the bottom dielectric layers and the source/drain trenches 420A/420B, and these small recesses will be filled with the material of inner spacers in the process of forming the inner spacers.

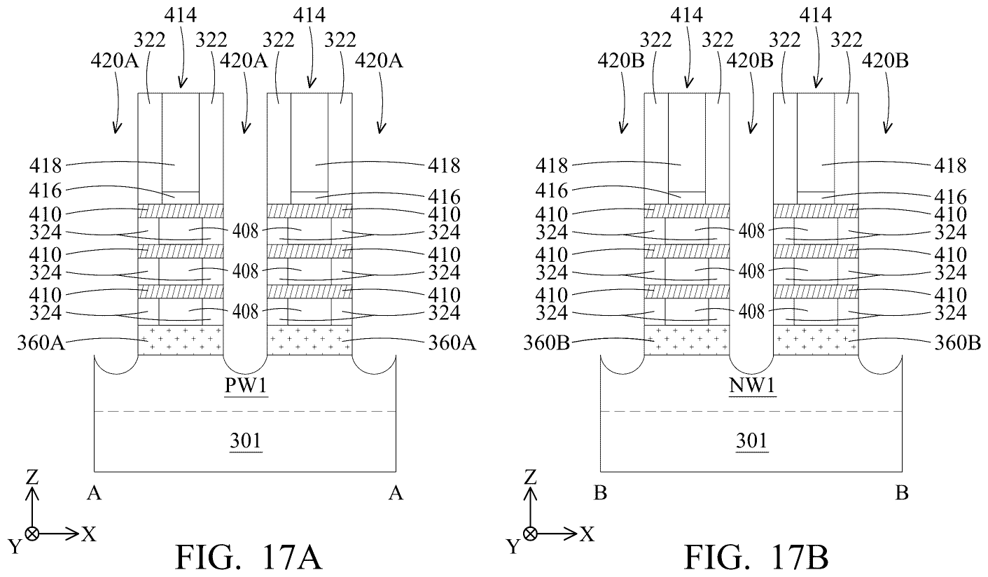

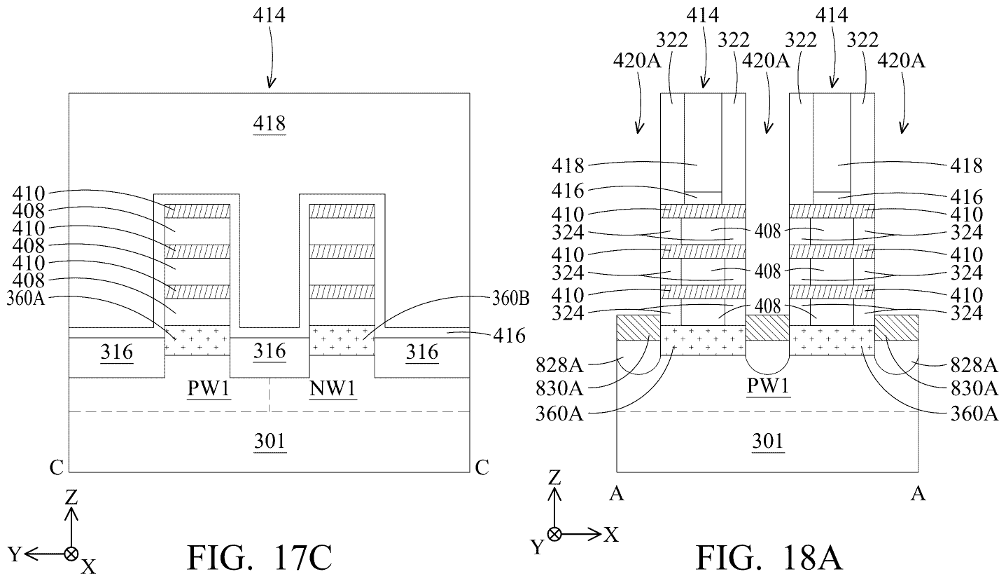

Referring to FIGS. 17A-17C, the inner spacers 324 are formed between the semiconductor layers 410 as well as between the semiconductor layer 410 and the bottom dielectric layers 360A or 360B, in accordance with some embodiments. In some embodiments, the semiconductor layers 408 exposed in the source/drain trenches 420A and 420B are partially recessed by a selective etching process, and the semiconductor layers 410 are not etched. More specifically, the selective etching process is performed that selectively etches the side portions of the semiconductor layers 408 below the gate spacers 322 through the source/drain trenches 420A and 420B, with minimal etching (or substantially no etching) of the semiconductor layers 410, the bottom dielectric layers 360A and 360B, and the substrate 301. After the selective etching process, inner spacer recesses are vertically formed between the semiconductor layers 410 as well as between the semiconductor layers 410 and the bottom dielectric layers 360A or 360B, below the gate spacers 322. The selective etching process may be a dry etching process, a wet etching process, other suitable etching process, or a combination thereof.

Next, in some embodiments, a spacer layer is conformally formed into the source/drain trenches 420A and 420B and the inner spacer recesses. More specifically, a deposition process is performed to form the spacer layer into the source/drain trenches 420A and 420B and the inner spacer recesses, such as CVD, PVD, ALD, HDPCVD, MOCVD, RPCVD, PECVD, LPCVD, ALCVD, APCVD, FCVD, other suitable methods, or combinations thereof. The spacer layer partially (and, in some embodiments, completely) fills the source/drain trenches 420A and 420B and fully fills the inner spacer recesses. The deposition process is configured to ensure that the spacer layer fills the inner spacer recesses. Furthermore, the spacer layer is also conformally formed on the gate spacers 322 and the isolation structures 316.

Then, in some embodiments, the inner spacers 324 are formed to fill the inner spacer recesses between the semiconductor layers 410, and between the semiconductor layer 410 and the bottom dielectric layers 360A or 360B. More specifically, an etching process is performed to selectively etch the spacer layer to form the inner spacers 324 with minimal etching (or substantially no etching) of the semiconductor layers 410, the bottom dielectric layers 360A and 360B, the substrate 301, the dummy gate structures 414, and the gate spacers 322. The etching process may be an anisotropic etching process, such that portions of the spacer layer that do not vertically overlap or be covered by the dummy gate structures 414 and the gate spacers 322 are removed. The spacer layer on the gate spacers 322 and the isolation structures 316 are also removed. The material and the dimension of the inner spacers 324 have been discussed above, and are not repeated herein.

In some embodiments, sidewalls of the inner spacers 324 are aligned to the sidewalls of the gate spacers 322 and the semiconductor layers 410. Therefore, the inner spacers 324 are formed on opposite sides of the dummy gate structure 414. In other embodiments, sidewalls of the inner spacers 324 have concave surfaces exposed by the source/drain trenches 420A or 420B. In some embodiments, sidewalls of the inner spacers 324 in contact with the semiconductor layers 408 have convex surfaces.

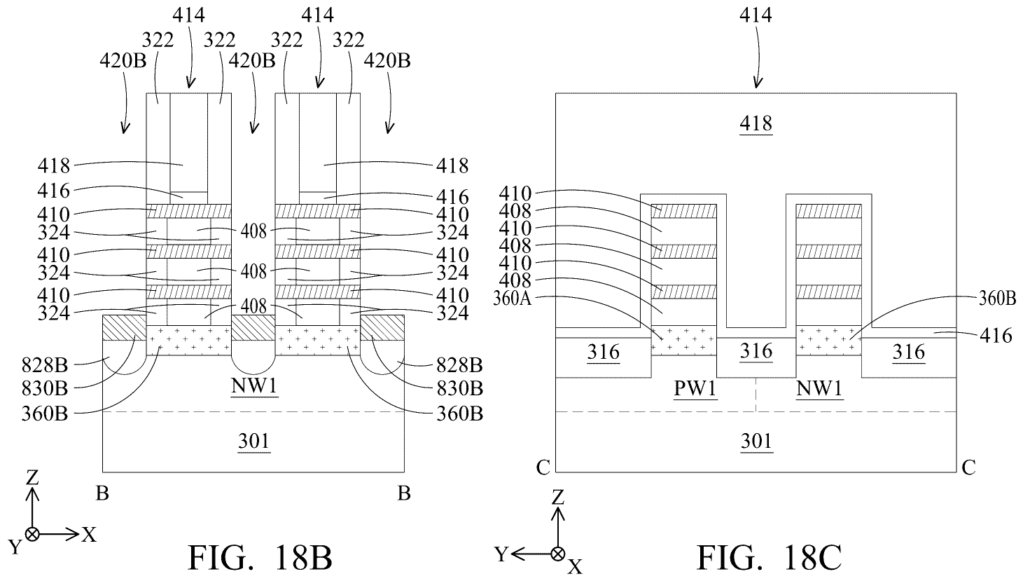

Referring to FIGS. 18A-18C, the undoped epitaxial layers 828A and 828B are formed in the bottom portions of the source/drain trenches 420A and 420B, respectively, in accordance with some embodiments. The material of forming the undoped epitaxial layers 828A and 828B has been discussed above, and are not repeated herein. In some embodiments, the undoped epitaxial layers 828A and 828B are epitaxially grown using an epitaxial growth to a specific height. In some embodiments, the specific height is dependent on the positions of the bottom dielectric layers 830A and 830B to be formed on the undoped epitaxial layers 828A and 828B. For example, when the positions of the bottom dielectric layers 830A and 830B are the same as or similar to that of the bottom dielectric layers 530A and 530B, the specific height is higher than the bottom surfaces but lower than the top surfaces of the bottom dielectric layers 360A and 360B. For example, when the positions of the bottom dielectric layers 830A and 830B are the same as or similar to that of the bottom dielectric layers 630A and 630B, the specific height is lower than the bottom surfaces of the bottom dielectric layers 360A and 360B. The epitaxial growth may be VPE, MOCVD, or MBE, although other deposition processes, such as CVD, LPCVD, PECVD, ALD, UHVCVD, RPCVD, combinations thereof, or the like, may also be utilized.

Still referring to FIGS. 18A-18C, the bottom dielectric layers 830A are formed in the source/drain trenches 420A and over the undoped epitaxial layers 828A, and the bottom dielectric layers 830B are formed in the source/drain trenches 420B and over the undoped epitaxial layers 828B, in accordance with some embodiments. In some embodiments, the bottom dielectric layers 830A and 830B may be formed by depositing a dielectric material layer in the source/drain trenches 420A and 420B, respectively. Then, an etching process is performed to remove the portions of the dielectric material layer on the sidewalls of the source/drain trenches 420A and 420B. After the etching process, the remaining portions of the dielectric material layer on the undoped epitaxial layers 828A and 828B become the bottom dielectric layers 830A and 830B, respectively.

In some embodiments, the thicknesses of the undoped epitaxial layers 828A and 828B are configured to control the positions of the source/drain bottom dielectric layers. For example, the top surfaces of the undoped epitaxial layers 828A and 828B can be formed higher, so that the top surfaces of the source/drain bottom dielectric layers formed on the undoped epitaxial layers 828A and 828B are higher than the top surfaces of the bottom dielectric layers 360A and 360B. That is, the positions of the source/drain bottom dielectric layers are the same as or similar to that of the bottom dielectric layers 830A and 830B shown in FIGS. 8A-8C or the bottom dielectric layers 330A and 330B shown in FIGS. 5A-5D. For example, the top surfaces of the undoped epitaxial layers 828A and 828B can be formed lower, so that the top surfaces of the source/drain bottom dielectric layers formed on the undoped epitaxial layers 828A and 828B are lower than the top surfaces of the bottom dielectric layers 360A and 360B. That is, the positions of the source/drain bottom dielectric layers are the same as or similar to that of the bottom dielectric layers 630A and 630B shown in FIGS. 6A-6C.

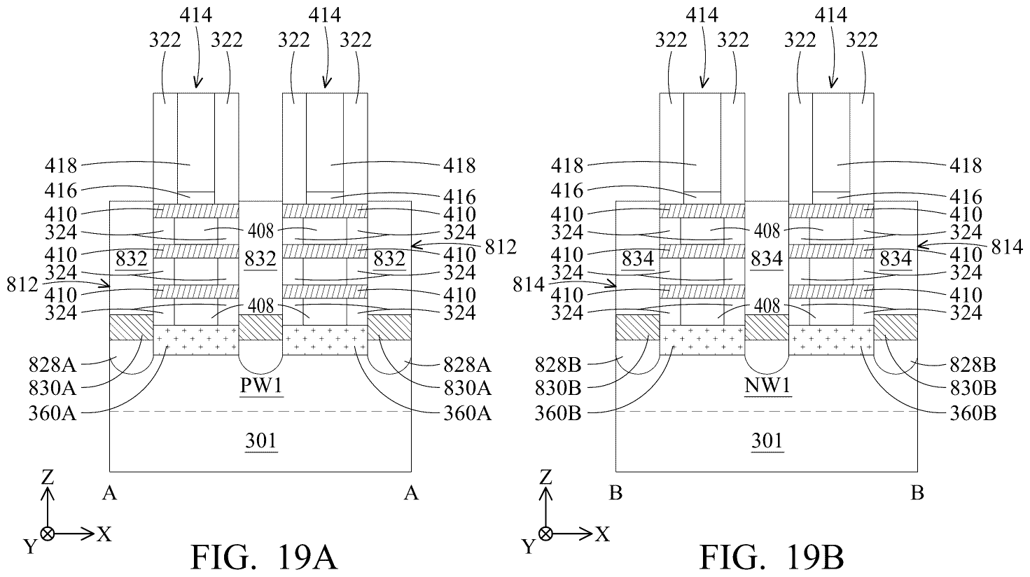

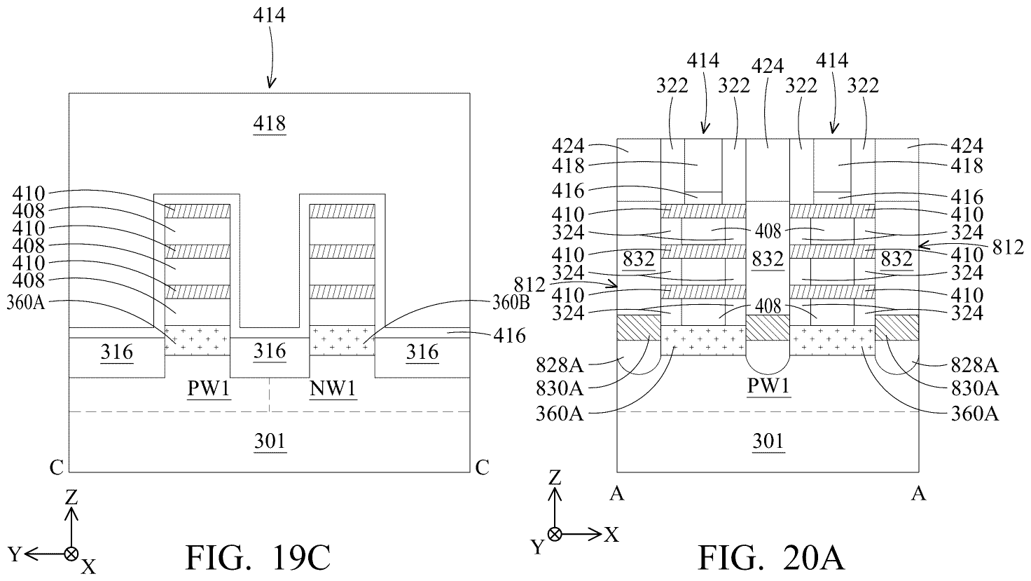

Referring to FIGS. 19A-19C, the epitaxial layers 832 are formed in the source/drain trenches 420A and the epitaxial layers 834 are formed in the source/drain trenches 420B, thereby forming the source/drain features 812 and the source/drain features 814, respectively, in accordance with some embodiments. The materials and methods used in forming the epitaxial layers 832 and 834 have been discussed above, and are not repeated herein. In some embodiments, each of the source/drain features 812 includes the undoped epitaxial layer 828A over the p-type well region PW1, the bottom dielectric layer 830A over the undoped epitaxial layer 828A, and the epitaxial layer 832 over the bottom dielectric layer 830A, as shown in FIG. 19A. In some embodiments, each of the source/drain features 814 includes the undoped epitaxial layer 828B over the n-type well region NW1, the bottom dielectric layer 830B over the undoped epitaxial layer 828B, and the epitaxial layer 834 over the bottom dielectric layer 830B, as shown in FIG. 19B.

In some embodiments, the formation of the epitaxial layers 832 and the formation of the epitaxial layers 834 are performed separately. For example, during the formation of the epitaxial layers 832, a first hard mask layer can be formed to cover the region including the source/drain trenches 420B while remaining the region including the source/drain trenches 420A exposed. Then, after the epitaxial layers 832 are formed in the source/drain trenches 420A, the first hard mask layer is removed. For example, during the formation of the epitaxial layers 834, a second hard mask layer can be formed to cover the region including the source/drain trenches 420A while remaining the region including the source/drain trenches 420B exposed. Then, after the epitaxial layers 834 are formed in the source/drain trenches 420B, the second hard mask layer is removed.

In some embodiments, each of the first hard mask layer and the second hard mask layer is formed by depositing a mask material layer, forming a photoresist layer on the mask material layer, patterning the photoresist layer, using the patterned photoresist layer as an etching mask to pattern the mask material layer, and removing the photoresist layer to form the first or second hard mask layer. In some embodiments, the first hard mask layer and the second hard mask layer may include a dielectric material, such as a high-k dielectric material.

In some embodiments, the formation of the undoped epitaxial layers 828A and 828B is omitted, such that the bottom dielectric layers 830A and 830B are in direct contact with the p-type well region PW1 and n-type well region NW1, respectively. In these embodiments, the resulting structure is the same as or similar to the structures shown in FIGS. 5A-5D or 6A-6C. In some embodiments, the formations of the undoped epitaxial layers 828A and 828B and the bottom dielectric layers 830B are omitted, such that the bottom dielectric layers 830A are in direct contact with the p-type well region PW1 and the epitaxial layers 834 are in direct contact with the n-type well region NW1. In these embodiments, the resulting structure is the same as or similar to the structure shown in FIGS. 7A-7C. In some embodiments, the formations of the bottom dielectric layers 830B is omitted, such that the epitaxial layers 834 are in direct contact with the undoped epitaxial layers 828B. In these embodiments, the resulting structure is the same as or similar to the structure shown in FIG. 9.

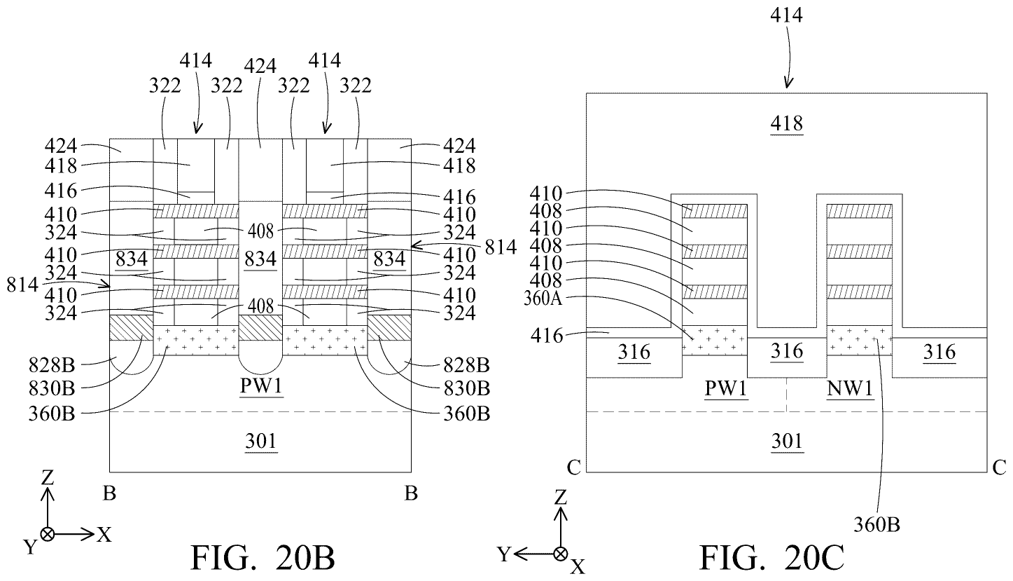

Referring to FIGS. 20A-20C, an ILD layer 424 is formed to fill the space between the gate spacers 322, in accordance with some embodiments. The ILD layer 424 may include tetraethylorthosilicate (TEOS) formed oxide, un-doped silicate glass, or doped silicon oxide such as BPSG, FSG, PSG, BSG, a low-k dielectric material, other suitable dielectric material, or combinations thereof. The ILD layer 424 may be formed by CVD, PVD, ALD, HDPCVD, MOCVD, RPCVD, PECVD, LPCVD, ALCVD, APCVD, FCVD, or other suitable methods. Subsequent to the formation of the ILD layer 424, a CMP process and/or other planarization process is performed on the ILD layer 424 until the top surfaces of the dummy gate structures 414 are exposed. In some embodiments, portions of the dummy gate electrodes 418 and the gate spacers 322 are removed after the planarization process.

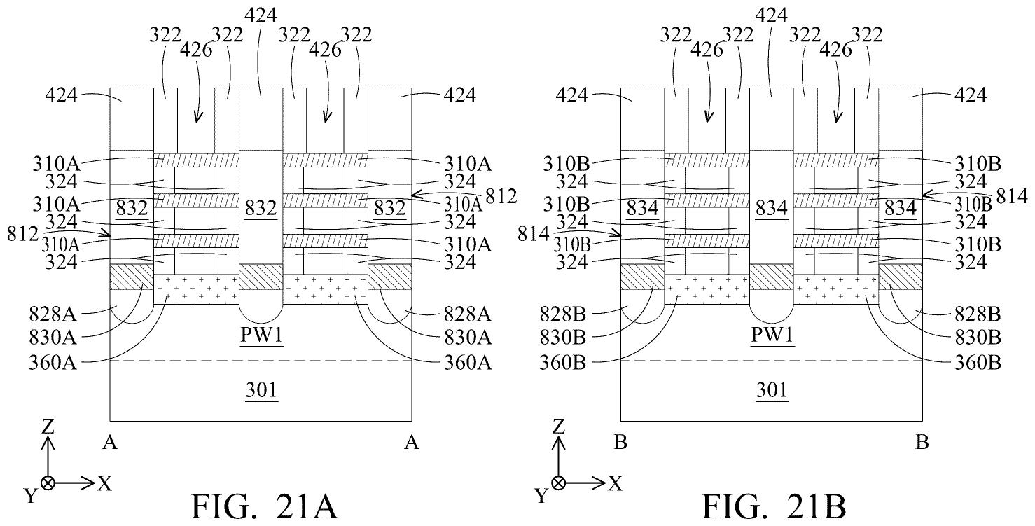

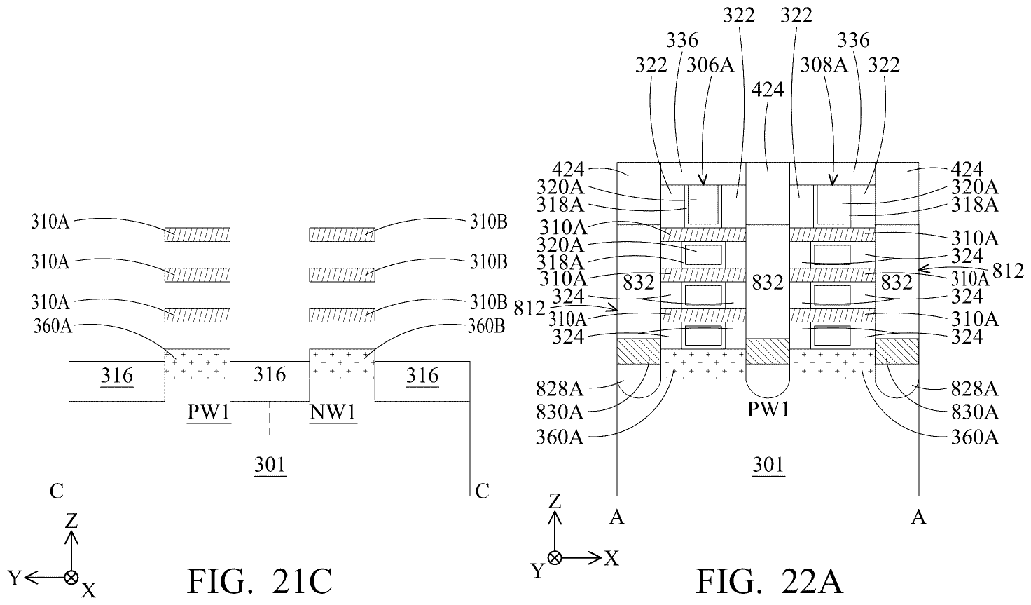

Referring to FIGS. 21A-21C, the dummy gate structures 414 are selectively removed through any suitable lithography and etching processes, in accordance with some embodiments. In some embodiments, the lithography process may include forming a photoresist layer (resist), exposing the resist to a pattern, performing a post-exposure bake process, and developing the resist to form a masking element, which exposes the region including the dummy gate structures 414. Then, the dummy gate structures 414 are selectively etched through the masking element. Etch selectivity may be achieved by selecting the appropriate etching chemicals, and the dummy gate structures 414 may be removed without substantially affecting the gate spacers 322, the inner spacers 324, and the substrate 301. The removal of the dummy gate structures 414 creates gate trenches 426. The gate trenches 426 expose the top surfaces of the topmost semiconductor layers 410 underlies the dummy gate structures 414.

Still referring to FIGS. 21A-21C, the semiconductor layers 408 are selectively removed through the gate trenches 426, using a wet or dry etching process for example, in accordance with some embodiments. After the semiconductor layers 408 are selectively removed, the semiconductor layers 410 are exposed in the gate trenches 426 to form the nanostructures 310A and 310B. In some embodiments, in each of the bottom dielectric layers 360A and 360B, a first portion of the top surfaces is exposed by the gate trenches 426, and the remaining portion of the top surface is covered by the bottommost pair of inner spacers 324. Such a process may also be referred to as a wire/nanowire/nanosheet release process, or a wire/nanowire/nanosheet formation process. The configurations of the nanostructures 310A and 310B have been discussed above, and are not repeated herein.

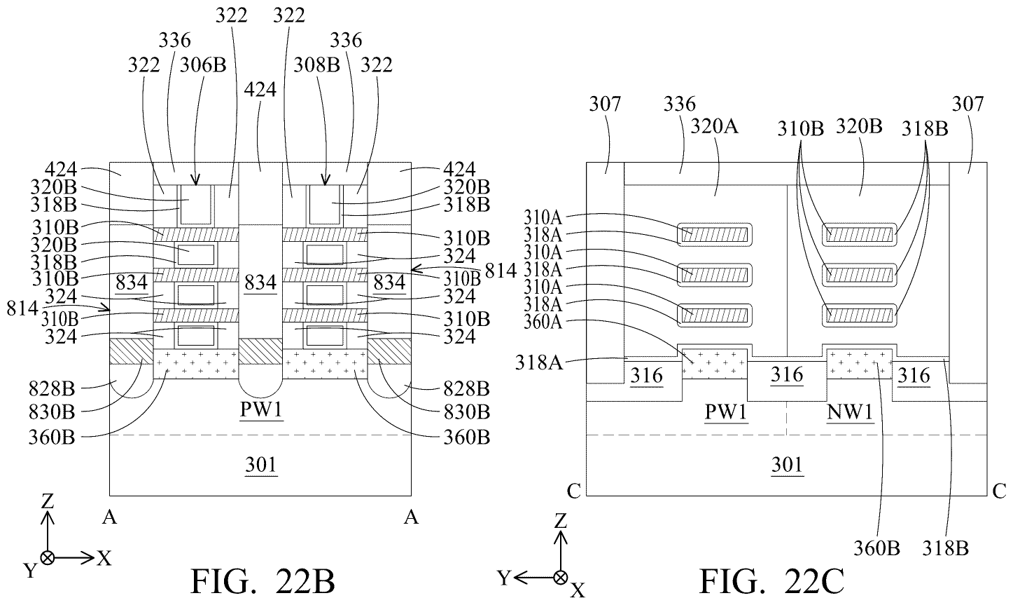

Referring to FIGS. 22A-22C, the gate structures 306A, 306B, 308A, and 308B discussed above are formed in the gate trenches 426, in accordance with some embodiments. In some embodiments, the gate structures 306A, 306B, 308A, and 308B wrap around each of the semiconductor layers 410, that is, wrap around each of the nanostructures 310A and 310B. In some embodiments, the gate structure 306A wraps around each of nanostructures 310A in corresponding vertical stack, the gate structure 308A wraps around each of nanostructures 310A in corresponding vertical stack, the gate structure 306B wraps around each of nanostructures 310B in corresponding vertical stack, and the gate structure 308B wraps around each of nanostructures 310B in corresponding vertical stack.

In some embodiments, the gate structures 306A and 308A each has the gate dielectric layer 318A and the gate electrode layer 320A. The gate dielectric layers 318A wrap around each of the nanostructures 310A, and the gate electrode layers 320A wrap around the gate dielectric layer 318A. In some embodiments, the gate structures 306B and 308B each has the gate dielectric layer 318B and the gate electrode layer 320B. The gate dielectric layers 318B wrap around each of the nanostructures 310B, and the gate electrode layers 320B wrap around the gate dielectric layer 318B. In some embodiments, the gate dielectric layers 318A and 318B are also formed on sidewalls of the inner spacers 324 and the gate spacers 322. The materials and methods used in forming the gate dielectric layers 318A, 318B and the gate electrode layers 320A, 320B have been discussed above, and are not repeated herein.

Still referring to FIGS. 22A-22C, after forming the gate structures 306A, 306B, 308A, and 308B, portions of the gate structures 306A, 306B, 308A, and 308B and the gate spacers 322 are recessed, and the gate top dielectrics 336 discussed above are formed over the gate structures 306A, 306B, 308A, and 308B and the gate spacers 322.

Still referring to FIGS. 22A-22C, gate end dielectrics 307 and gate end dielectrics 309 (see FIG. 4) are formed in the gate structures 306A, 306B, 308A, and 308B, in accordance with some embodiments. The materials and methods used in forming the gate end dielectrics 307 and 309 have been discussed above, and are not repeated herein.

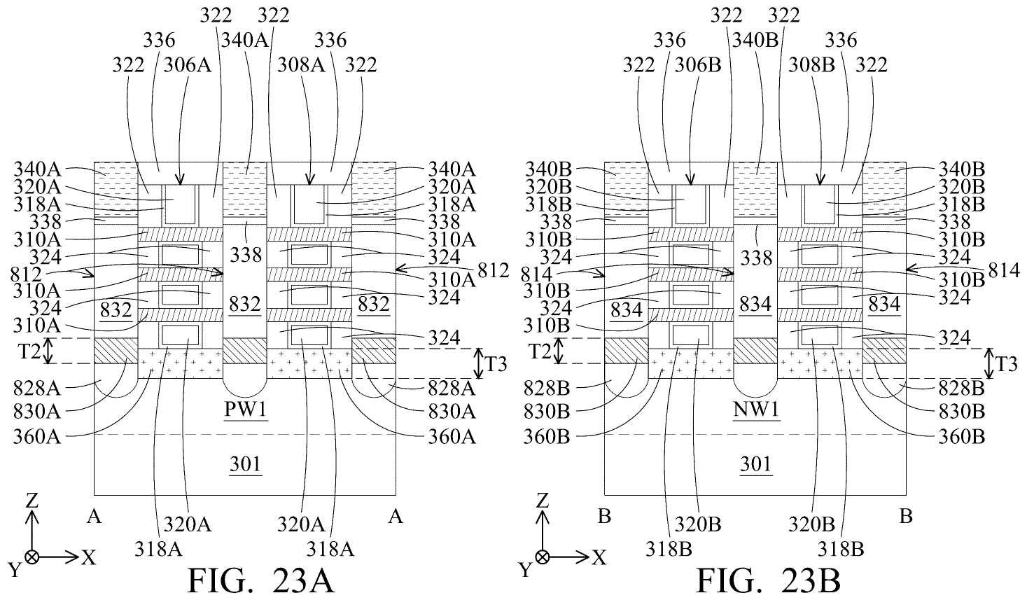

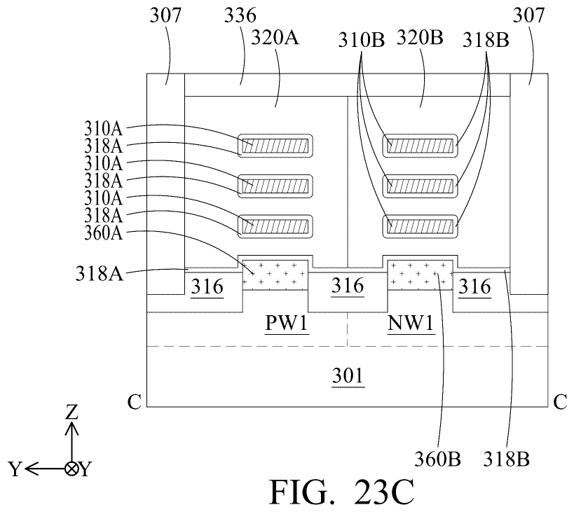

Referring to FIGS. 23A-23C, the source/drain contacts 340 discussed above are formed in the ILD layer 424, in accordance with some embodiments. In some embodiments, the source/drain contacts 340A are over and electrically connected to the respective source/drain features 812. In some embodiments, two source/drain contacts 340A are on the opposite sides of the gate structure 306A, and two source/drain contacts 340A are on the opposite sides of the gate structure 308A. In some embodiments, the source/drain contacts 340B are over and electrically connected to the respective source/drain features 814. In some embodiments, two source/drain contacts 340B are on the opposite sides of the gate structure 306B, and two source/drain contacts 340B are on the opposite sides of the gate structure 308B. The materials and methods used in forming the source/drain contacts 340 have been discussed above, and are not repeated herein.

In some embodiments, additional features are formed between the source/drain features 812, 814 and the source/drain contacts 340, such as the silicide layers 338 discussed above. As such, the transistors in the semiconductor structure 300 are formed.

After the operation shown in FIGS. 23A-23C, the further processes may be performed to complete the semiconductor structure 300. After the further processes, the resulting structure may be the same as or similar to the structure shown in FIGS. 8A-8C. For example, the ILD layer 342 may be formed over the structure shown in FIGS. 23A-23C, and the gate vias 346A-346B and the source/drain vias 348A-348E may be formed in the ILD layer 342. For example, the IMD layer 344 may be formed over the ILD layer 342, and the metal layer M1 (e.g., the metal conductors 350A-350G) may be formed in the IMD layer 344.

The embodiments disclosed herein are related to semiconductor structures, and more particularly to semiconductor structures including MOSFETs with gate bottom dielectric layers and source/drain bottom dielectric layers. The gate bottom dielectric layers are formed below the gate structure and between the gate structures and the underlying substrate, and the source/drain bottom dielectric layers are formed below the source/drain regions and between the source/drain regions and the underlying substrate. The present embodiments provide one or more of the following advantages. The gate bottom dielectric layers located below the gate structures can reduce the Isoff, and reduce the capacitance between the gate structure and well region. The source/drain bottom dielectric layers located below the source/drain regions can reduce the Iboff and the Isoff, and reduce the capacitance between the source/drain regions and the substrate. Moreover, the provided structure with the gate and source/drain bottom dielectric layers allows lower APT dosage or omitting the APT process, and thus the performance of threshold voltage (Vt) mismatch can be improved.

In one exemplary aspect, the present disclosure is directed to a semiconductor structure. The semiconductor structure includes a substrate, first nanostructures that are vertically arranged over the substrate, and a first gate structure that is wrapped around each of the first nanostructures. The semiconductor structure further includes first gate spacers that are formed on opposite sides of the first gate structure and over a topmost one of the first nanostructures, first source/drain features that are attached to opposite sides of the first nanostructures, and a second bottom dielectric layer that is formed over the substrate and below the first gate structure. Each of the first source/drain features includes a first bottom dielectric layer and a first epitaxial layer over the first bottom dielectric layer. The first bottom dielectric layer is vertically sandwiched between the substrate and the first epitaxial layer. The second bottom dielectric layer is vertically sandwiched between the substrate and the first gate structure, and the second bottom dielectric layer is in contact with the first bottom dielectric layers.

In another exemplary aspect, the present disclosure is directed to a semiconductor structure. The semiconductor structure includes a substrate and a first complementary metal-oxide-semiconductor (CMOS) device. The first CMOS device includes a first transistor and a second transistor formed on the substrate. The first transistor includes first nanostructures vertically arranged over the substrate, a first gate structure wrapped around each of the first nanostructures, and first source/drain features attached to opposite sides of the first nanostructures. Each of the first source/drain features includes a first bottom dielectric layer and a first epitaxial layer over the first bottom dielectric layer. The first transistor further includes a second bottom dielectric layer formed over the substrate and below the first gate structure. The second bottom dielectric layer is vertically sandwiched between the substrate and the first gate structure. The second transistor includes second nanostructures vertically arranged over the substrate, a second gate structure wrapped around each of the second nanostructures and engaging with the first gate structure, and second source/drain features attached to opposite sides of the second nanostructures. Each of the second source/drain features includes a second epitaxial layer. The second transistor further includes a third bottom dielectric layer formed over the substrate and below the second gate structure. The third bottom dielectric layer is vertically sandwiched between the substrate and the second gate structure

In yet another exemplary aspect, the present disclosure is directed to a method of forming a semiconductor structure. The method includes forming a fin structure over a substrate, forming a dummy gate structure over the fin structure, and forming source/drain trenches in the fin structure on opposite sides of the dummy gate structure. The fin structure includes a first semiconductor layer over the substrate, and second semiconductor layers and third semiconductor layers stacked in an alternating manner over the first semiconductor layer. The method further includes removing the first semiconductor layer through the source/drain trenches to form a first recess, depositing a first dielectric material in the first recess to form a first bottom dielectric layer, and forming a second bottom dielectric layer in each of the source/drain trenches. The method further includes forming a first epitaxial layer on the second bottom dielectric layer in each of the source/drain trenches, such that the second bottom dielectric layer is vertically between the substrate and the first epitaxial layer, and removing the dummy gate structure and the second semiconductor layers to form a gate trench. The gate trench exposes a first portion of a top surface of the first bottom dielectric layer. The method further includes forming a gate structure in the gate trench. The gate structure is wrapped around each of the third semiconductor layers, and covers the first portion of the top surface of the first bottom dielectric layer.

In yet another exemplary aspect, the present disclosure is directed to a semiconductor structure. The semiconductor structure includes a substrate, first nanostructures vertically arranged over the substrate, and a first gate structure wrapped around each of the first nanostructures. The semiconductor structure further includes first inner spacers formed on opposite sides of the first gate structure and separating the first nanostructures from each other, first source/drain features attached to opposite sides of the first nanostructures, and a second bottom dielectric layer formed over the substrate and laterally extending under the first gate structure and a bottommost pair of the first inner spacers. Each of the first source/drain features includes a first bottom dielectric layer and a first epitaxial layer over the first bottom dielectric layer, and the first bottom dielectric layer is vertically sandwiched between the substrate and the first epitaxial layer.

In some embodiments, the first bottom dielectric layers are in contact with the bottommost pair of the first inner spacers and the second bottom dielectric layer, and first top surfaces of the first bottom dielectric layers are higher than a second top surface of the second bottom dielectric layer by about 1 nm to about 5 nm.

In some embodiments, the semiconductor structure further includes second nanostructures vertically arranged over the substrate, a second gate structure wrapped around each of the second nanostructures, second source/drain features attached to opposite sides of the second nanostructures, and a fourth bottom dielectric layer formed over the substrate and laterally extending under the second gate structure. Each of the second source/drain features includes a second undoped epitaxial layer and a second epitaxial layer over the second undoped epitaxial layer.

In some embodiments, each of the first source/drain features further includes a first undoped epitaxial layer below the first bottom dielectric layer. The first bottom dielectric layer is between the first undoped epitaxial layer and the first epitaxial layer. The second source/drain features are free of a dielectric material between the second undoped epitaxial layer and the second epitaxial layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate;
first nanostructures, vertically arranged over the substrate;
a first gate structure, wrapped around each of the first nanostructures;
first gate spacers, formed on opposite sides of the first gate structure and over a topmost one of the first nanostructures;
first source/drain features, attached to opposite sides of the first nanostructures, wherein each of the first source/drain features comprises a first bottom dielectric layer and a first epitaxial layer over the first bottom dielectric layer, and wherein the first bottom dielectric layer is vertically sandwiched between the substrate and the first epitaxial layer; and
a second bottom dielectric layer, formed over the substrate and below the first gate structure, wherein the second bottom dielectric layer is vertically sandwiched between the substrate and the first gate structure, and wherein the second bottom dielectric layer is in contact with the first bottom dielectric layers.

2. The semiconductor structure of claim 1, further comprising:
first inner spacers, formed on opposite sides of the first gate structure and separating the first nanostructures from each other,
wherein the second bottom dielectric layer is below the first inner spacers and vertically sandwiched between the substrate and a bottommost pair of the first inner spacers.

3. The semiconductor structure of claim 2, wherein sidewalls of the first bottom dielectric layers are in partial contact with sidewalls of the bottommost pair of the first inner spacers and in partial contact with sidewalls of the second bottom dielectric layer.

4. The semiconductor structure of claim 1, wherein a ratio of a second thickness of the second bottom dielectric layer to a first thickness of the first bottom dielectric layer is in a range from about 1.1 to about 3.

5. The semiconductor structure of claim 1, further comprising:
second nanostructures, vertically arranged over the substrate;
a second gate structure, wrapped around each of the second nanostructures;
second source/drain features, attached to opposite sides of the second nanostructures; and
a third bottom dielectric layer, formed over the substrate and below the second gate structure, wherein the third bottom dielectric layer is vertically sandwiched between the substrate and the second gate structure.

6. The semiconductor structure of claim 5, wherein each of the second source/drain features further comprises:
a fourth bottom dielectric layer and a second epitaxial layer over the second bottom dielectric layer,
wherein the fourth bottom dielectric layer is vertically sandwiched between the substrate and the second epitaxial layer.

7. The semiconductor structure of claim 6,
wherein first top surfaces of the first bottom dielectric layers are higher than a second top surface of the second bottom dielectric layer, and
wherein fourth top surfaces of the fourth bottom dielectric layers are lower than a third top surface of the third bottom dielectric layer.

8. The semiconductor structure of claim 1, wherein each of the first source/drain features further comprises:
an undoped epitaxial layer below the first bottom dielectric layer,
wherein the undoped epitaxial layer is vertically sandwiched between the substrate and the first bottom dielectric layer.

9. A semiconductor structure, comprising:
a substrate; and
a first complementary metal-oxide-semiconductor (CMOS) device, comprising a first transistor and a second transistor formed on the substrate,
wherein the first transistor comprises:
first nanostructures, vertically arranged over the substrate;
a first gate structure, wrapped around each of the first nanostructures;
first source/drain features, attached to opposite sides of the first nanostructures, wherein each of the first source/drain features comprises a first bottom dielectric layer and a first epitaxial layer over the first bottom dielectric layer; and
a second bottom dielectric layer, formed over the substrate and below the first gate structure, wherein the second bottom dielectric layer is vertically sandwiched between the substrate and the first gate structure;
wherein the second transistor comprises:
second nanostructures, vertically arranged over the substrate;
a second gate structure, wrapped around each of the second nanostructures and engaging with the first gate structure;
second source/drain features, attached to opposite sides of the second nanostructures, wherein each of the second source/drain features comprises a second epitaxial layer; and
a third bottom dielectric layer, formed over the substrate and below the second gate structure, wherein the third bottom dielectric layer is vertically sandwiched between the substrate and the second gate structure.

10. The semiconductor structure of claim 9,
wherein each of the first source/drain features further comprises a first undoped epitaxial layer below the first bottom dielectric layer, and wherein the first undoped epitaxial layer is vertically sandwiched between the substrate and the first bottom dielectric layer, and
wherein each of the second source/drain features further comprises a second undoped epitaxial layer below the second epitaxial layer, and wherein the second undoped epitaxial layer is vertically sandwiched between the substrate and the second epitaxial layer.

11. The semiconductor structure of claim 10, wherein the second undoped epitaxial layer is in direct contact with the second epitaxial layer.

12. The semiconductor structure of claim 9, wherein thicknesses of the second bottom dielectric layer and the third bottom dielectric layer are in a range from about 4 nm to about 30 nm.

13. The semiconductor structure of claim 9, wherein each of the second source/drain features further comprises:
a fourth bottom dielectric layer below the second epitaxial layer,
wherein the fourth bottom dielectric layer is vertically sandwiched between the substrate and the second epitaxial layer.

14. The semiconductor structure of claim 13,
wherein first top surfaces of the first bottom dielectric layers are higher than a second top surface of the second bottom dielectric layer, and
wherein fourth top surfaces of the fourth bottom dielectric layers are lower than a third top surface of the third bottom dielectric layer.

15. The semiconductor structure of claim 9, further comprising:
a gate top dielectric, formed on the first gate structure and the second gate structure;
an inter-layer dielectric (ILD) layer, formed on the gate top dielectric; and
a gate via, extending through the ILD layer and the gate top dielectric, so as to be in contact with the first gate structure.

16. The semiconductor structure of claim 9, further comprising:
isolation structures, formed below the first gate structure and the second gate structure, and surrounding the second bottom dielectric layer and the third bottom dielectric layer,
wherein a first top surface of the second bottom dielectric layer and a second top surface of the third bottom dielectric layer are higher than third top surfaces of the isolation structures.

17. A method of forming a semiconductor structure, comprising:
forming a fin structure over a substrate, wherein the fin structure comprises a first semiconductor layer over the substrate, and second semiconductor layers and third semiconductor layers stacked in an alternating manner over the first semiconductor layer;
forming a dummy gate structure over the fin structure;
forming source/drain trenches in the fin structure on opposite sides of the dummy gate structure;
removing the first semiconductor layer through the source/drain trenches to form a first recess;
depositing a first dielectric material in the first recess to form a first bottom dielectric layer;
forming a second bottom dielectric layer in each of the source/drain trenches;
forming a first epitaxial layer on the second bottom dielectric layer in each of the source/drain trenches, such that the second bottom dielectric layer is vertically between the substrate and the first epitaxial layer;
removing the dummy gate structure and the second semiconductor layers to form a gate trench, wherein the gate trench exposes a first portion of a top surface of the first bottom dielectric layer; and
forming a gate structure in the gate trench, wherein the gate structure is wrapped around each of the third semiconductor layers, and covers the first portion of the top surface of the first bottom dielectric layer.

18. The method of claim 17, further comprising:
partially recessing the second semiconductor layers exposed in the source/drain trenches to form inner spacer recesses; and
forming inner spacers in the inner spacer recesses, wherein a bottommost pair of the inner spacers is in contact with and covers a second portion of the top surface of the first bottom dielectric layer,
wherein the first bottom dielectric layer is vertically between the substrate and the bottommost pair of the inner spacers and the gate structure.

19. The method of claim 18, further comprising:
forming gate spacers on opposite sidewalls of the dummy gate structure and over a topmost one of the third semiconductor layers,
wherein widths of the gate spacers are greater than widths of the inner spacers.

20. The method of claim 17, further comprising:
forming an undoped epitaxial layer at a bottom of each of the source/drain trenches,
wherein the second bottom dielectric layer is formed on the undoped epitaxial layer, and wherein a second top surface of the second bottom dielectric layer is higher than a first top surface of the first bottom dielectric layer.
